(19) United States
(12) Patent Application Publication
(10) Pub. No.: US 2016/0141234 A1
(43) Pub. Date: May 19, 2016

(54) INTEGRATED DEVICE PACKAGE COMPRISING SILICON BRIDGE IN PHOTO IMAGEABLE LAYER

(71) Applicant: QUALCOMM Incorporated, San Diego, CA (US)

(72) Inventors: Hong Bok We, San Diego, CA (US); Dong Wook Kim, San Diego, CA (US); Jae Sik Lee, San Diego, CA (US); Kyu-Pyung Hwang, San Diego, CA (US); Young Kyu Song, San Diego, CA (US)

(21) Appl. No.: 14/543,560

(22) Filed: Nov. 17, 2014

(51) Int. Cl. H01L 23/498

(52) U.S. Cl. CPC H01L 23/49811; H01L 23/49822; H01L 23/49827; H01L 23/49838

(57) ABSTRACT

An integrated device package includes a base portion, a redistribution portion, a first die and a second die. The base portion includes a photo imageable layer, a bridge that is at least partially embedded in the photo imageable layer, and a set of vias in the photo imageable layer. The bridge includes a first set of interconnects comprising a first density. The set of vias includes a second density. The redistribution portion is coupled to base portion. The redistribution portion includes at least one dielectric layer, a second set of interconnects coupled to the first set of interconnects, and a third set of interconnects coupled to the set of vias. The first die is coupled to the redistribution portion. The second die is coupled to the redistribution portion, where the first die and the second die are coupled to each other through an electrical path that includes the bridge.

### BACKGROUND

1. Field

Various features relate to an integrated device package that includes a silicon bridge in a photo imageable layer.

2. Background

FIG. 1 illustrates a conventional configuration of an integrated package that includes multiple dies. Specifically, FIG. 1 illustrates an integrated package 100 that includes a package substrate 104, a first die 106, and a second die 108. The integrated package 100 is coupled to a printed circuit board (PCB) 102 through a first set of solder balls 105. The first die 106 is coupled to the package substrate 104 through a second set of solder balls 107. The second die 108 is coupled to the package substrate 104 through a third set of solder balls 109. The package substrate 104 includes one or more dielectric layers 110, and a set of interconnects 112 (e.g., traces and vias). The set of interconnects 112 is coupled to the first, second, and third set of solder balls 105, 107, and 109. The first die 106 and the second die 108 may be electrically coupled to each other through the second set of solder balls 107, the set of interconnects 112, and the third set of solder balls 109.

One drawback of the integrated package 100 shown in FIG. 1 is that it creates an integrated device with a form factor that may be too large for the needs of mobile computing devices. This may result in a package that is either too large and/or too thick. That is, the integrated package configuration shown in FIG. 1 may be too thick and/or have a surface area that is too large to meet the needs and/or requirements of mobile computing devices.

Another drawback of the integrated package 100 is that the configuration of the set of interconnects 112 does not provide high density interconnects between the first die 106 and the second die 108. This greatly limits the number of interconnects that can exist between the first and second dies 106 and 108, therefore limiting the communication bandwidth between the first and second dies 106 and 108.

Therefore, there is a need for an integrated device that includes high density interconnects between dies. Ideally, such an integrated device will have a better form factor, while at the same time meeting the needs and/or requirements of mobile computing devices.

### SUMMARY

Various features, apparatus and methods described herein an integrated device package that includes a silicon bridge in a photo imageable layer.

A first example provides an integrated device package base that includes a base portion and a redistribution portion. The base portion includes (i) a photo imageable layer, (ii) a bridge, at least partially embedded in the photo imageable layer, configured to provide an electrical path between a first die and a second die, the bridge comprising a first set of interconnects comprising a first density of interconnection, and (iii) a set of vias, in the photo imageable layer, comprising a second density of interconnection. The redistribution portion is coupled to the base portion. The redistribution portion includes at least one dielectric layer, a second set of interconnects coupled to the first set of interconnects, a third set of interconnects coupled to the set of vias.

According to an aspect, the first density of interconnection of the first set of interconnects is less than the second density of interconnection of the set of vias.

According to one aspect, the first density of interconnection of the first set of interconnects comprises a width of about 2 microns (μm) or less, and/or a spacing of about 2 microns (μm) or less.

According to an aspect, the electrical path between the first die and the second die comprises the first set of interconnects in the bridge and the second set of interconnects in the redistribution portion.

According to one aspect, the first set of interconnects comprises one of at least a trace, a via, and/or a pad.

According to an aspect, the second set of interconnects comprises one of at least a redistribution interconnect, a trace, a via, and/or a pad.

According to one aspect, the integrated device package base is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

A second example provides an integrated device package base that includes a base portion and a redistribution portion. The base portion includes (i) a photo imageable layer, (ii) a bridge means, at least partially embedded in the photo imageable layer, configured to provide an electrical path between a first die and a second die, and (iii) a set of vias in the photo imageable layer. The redistribution portion is coupled to the base portion. The redistribution portion includes at least one dielectric layer, a first set of interconnects coupled to the bridge means, and a second set of interconnects coupled to the set of vias.

According to an aspect, the bridge means includes a third set of interconnects comprising a first density of interconnection, the first density of interconnection comprising a width of about 2 microns (μm) or less, and/or a spacing of about 2 microns (μm) or less.

According to an aspect, the third set of interconnects comprises one of at least a trace, a via, and/or a pad.

According to an aspect, the electrical path between the first die and the second die comprises the third set of interconnects in the bridge and the first set of interconnects in the redistribution portion.

According to an aspect, the second set of interconnects comprises one of at least a redistribution interconnect, a trace, a via, and/or a pad.

According to an aspect, the integrated device package base is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

A third example provides an integrated device package that includes a base portion, a redistribution portion, a first die and a second die. The base portion includes (i) a photo imageable layer, (ii) a bridge, at least partially embedded in the photo imageable layer, comprising a first set of interconnects comprising a first density of interconnection, (iii) a set of vias, in the photo imageable layer, comprising a second density of interconnection. The redistribution portion is coupled to the base portion. The redistribution portion includes at least one dielectric layer, a second set of interconnects coupled to the first set of interconnects, and a third set of interconnects coupled to the set of vias. The first die is coupled to the redistribution portion. The second die is coupled to the redistribution portion, where the first die and the second die are coupled to each other through an electrical path that includes the bridge.

According to an aspect, the first density of interconnection of the first set of interconnects is less than the second density of interconnection of the set of vias.

According to one aspect, the first density of interconnection of the first set of interconnects comprises a width of about 2 microns (μm) or less, and/or a spacing of about 2 microns (μm) or less.

According to an aspect, the electrical path between the first die and the second die comprises the first set of interconnects in the bridge and the second set of interconnects in the redistribution portion.

According to one aspect, the first set of interconnects comprises one of at least a trace, a via, and/or a pad.

According to an aspect, the second set of interconnects comprises one of at least a redistribution interconnect, a trace, a via, and/or a pad.

According to one aspect, the integrated device package further includes a fill between the first die and the redistribution portion.

According to an aspect, the integrated device package is a first integrated device package of a package-on-package (PoP) structure.

According to one aspect, the integrated device package is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

A fourth example provides an integrated device package that includes a base portion, a redistribution portion, a first die, and a second die. The base portion includes a photo imageable layer, a bridge means at least partially embedded in the photo imageable layer, a set of vias in the photo imageable layer. The redistribution portion is coupled to the base portion. The redistribution portion includes at least one dielectric layer, a first set of interconnects coupled to the bridge means, and a second set of interconnects coupled to the set of vias. The first die is coupled to the redistribution portion. The second die is coupled to the redistribution portion. The first die and the second die are coupled to each other through an electrical path that includes the bridge means, wherein the bridge means is configured to provide an electrical path between a first die and a second die.

According to an aspect, the bridge means includes a third set of interconnects comprising a first density of interconnection, the first density of interconnection comprising a width of about 2 microns (μm) or less, and/or a spacing of about 2 microns (μm) or less.

According to one aspect, the third set of interconnects comprises one of at least a trace, a via, and/or a pad.

According to an aspect, the electrical path between the first die and the second die comprises the third set of interconnects in the bridge means and the first set of interconnects in the redistribution portion.

According to one aspect, the second set of interconnects comprises one of at least a redistribution interconnect, a trace, a via, and/or a pad.

According to an aspect, the integrated device package further includes a fill between the first die and the redistribution portion.

According to one aspect, the integrated device package is a first integrated device package of a package-on-package (PoP) structure.

According to an aspect, the integrated device package is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

### DRAWINGS

Various features, nature and advantages may become apparent from the detailed description set forth below when taken in conjunction with the drawings in which like reference characters identify correspondingly throughout.

FIG. 1 illustrates a conventional integrated package comprising two dies.

FIG. 2 illustrates an example of an integrated device package comprising a high density interconnect silicon bridge in a photo imageable layer.

FIG. 3 illustrates an example of a profile view of a high density interconnect silicon bridge.

FIG. 4 illustrates an example of a plan view of a high density silicon interconnect bridge.

FIG. 5 illustrates an example of a profile view of an integrated device package base comprising a high density interconnect silicon bridge in a photo imageable layer.

FIG. 6 illustrates an example of a profile view of an integrated device package base comprising a high density interconnect silicon bridge in a photo imageable layer.

FIG. 7 illustrates an example of a profile view of an integrated device package base comprising a high density interconnect silicon bridge in a photo imageable layer.

FIG. 8 illustrates an example of a profile view of an integrated device package base comprising a high density interconnect silicon bridge in a photo imageable layer.

FIG. 9 illustrates an example of a profile view of an integrated device package comprising a high density silicon interconnect bridge in a photo imageable layer.

FIG. 10 illustrates an example of a profile view of an integrated device package comprising a high density interconnect silicon bridge in a photo imageable layer.

FIG. 11 illustrates an exemplary sequence for providing/fabricating a high density interconnect silicon bridge.

FIG. 12 illustrates an exemplary flow diagram of a method for providing/fabricating a high density interconnect silicon bridge.

FIG. 13 (comprising 13A-13D) illustrates an exemplary sequence for providing/fabricating an integrated device package comprising a high density silicon bridge in a photo imageable layer.

FIG. 14 illustrates an exemplary flow diagram of a method for providing/fabricating an integrated device package comprising a high density silicon bridge in a photo imageable layer.

FIG. 15 illustrates an example of a semi-additive patterning (SAP) process.

FIG. 16 illustrates an example of flow diagram of a semi-additive patterning (SAP) process.

FIG. 17 illustrates an example of a damascene process.

FIG. 18 illustrates an example of a flow diagram of a damascene process.

FIG. 19 illustrates a package-on-package (POP) structure comprising a high density silicon bridge in a photo imageable layer.

FIG. 20 illustrates various electronic devices that may integrate a semiconductor device, a die, an integrated circuit and/or PCB described herein.

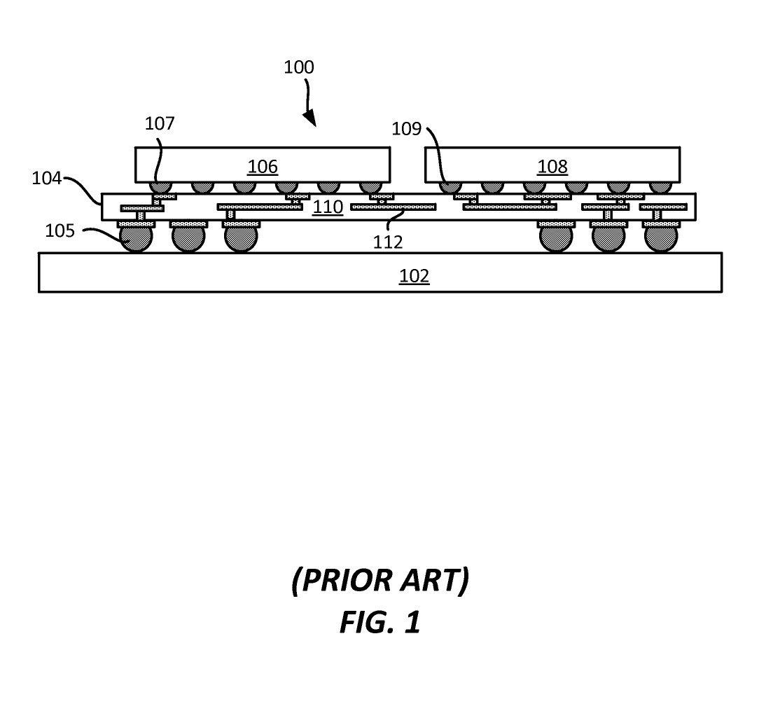

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

### Overview

Some novel features pertain to an integrated device package that includes a base portion, a redistribution portion, a first die and a second die. The base portion includes a photo imageable layer, a bridge that is at least partially embedded in the photo imageable layer, and a set of vias in the photo imageable layer. The bridge includes a first set of interconnects comprising a first density. The set of vias includes a second density. The redistribution portion is coupled to base portion. The redistribution portion includes at least one dielectric layer, a second set of interconnects coupled to the first set of interconnects, and a third set of interconnects coupled to the set of vias. The first die is coupled to the redistribution portion. The second die is coupled to the redistribution portion, where the first die and the second die are coupled to each other through an electrical path that includes the bridge. In some implementations, the bridge is configured to provide a high density die-to-die interconnect between the first and second dies. In some implementations, the first density of the first set of interconnects is less than the second density of the set of vias. In some implementations, the first density of the first set of interconnects includes a width of about 2 microns (μm) or less, and/or a spacing of about 2 microns (μm) or less. In some implementations, the electrical path between the first die and the second die includes the first set of interconnects in the bridge and the second set of interconnects in the redistribution portion. In some implementations, the integrated device package includes a fill between the first die and the redistribution portion.

An interconnect is an element or component of a device (e.g., integrated device, integrated device package, die) and/or a base (e.g., package substrate, printed circuit board, interposer) that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect is an electrically conductive material that provides an electrical path for a signal (e.g., data signal, ground signal, power signal). An interconnect may include more than one element/component.

A redistribution layer or a redistribution metal layer is a metal layer of a redistribution portion of an integrated device or an integrated device package. A redistribution layer may include one or more redistribution interconnects, which are formed on the same metal layer of the redistribution portion. A redistribution portion of an integrated device may include several redistribution layers, each redistribution layer may include one or more redistribution interconnects. Thus, for example, a redistribution portion may include a first redistribution interconnect on a first redistribution layer, and a second redistribution interconnect on a second redistribution layer that is different than the first redistribution layer.

A photo imageable layer/material is a material that is photo etchable. That is, the photo imageable layer/material is made of a material that can be etched and/or removed (e.g., through a lithography process) through the exposure of the material to a light source (e.g., ultraviolet (UV) light) through a mask (e.g., photomask).

### Exemplary Integrated Device Package Comprising Silicon Bridge in Photo Imageable Layer

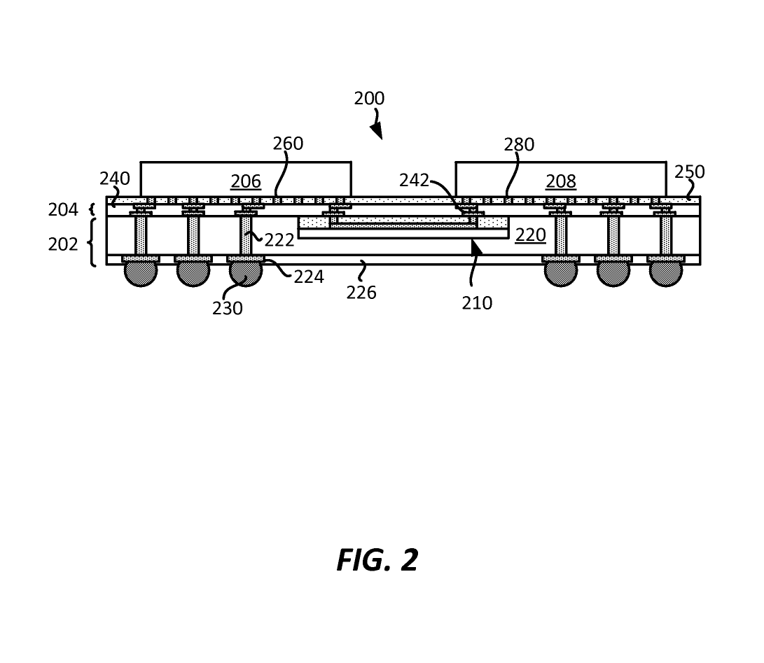

FIG. 2 illustrates an example of an integrated device package that includes high density die-to-die interconnects. Specifically, FIG. 2 illustrates an example of an integrated device package 200 that includes a base portion 202, a redistribution portion 204, a first die 206, a second die 208, and a silicon bridge 210. The silicon bridge 210 is configured to provide high density die-to-die interconnects in the integrated device package 200. High density interconnects may refer to any density of wiring or connections per unit area than conventional printed circuit boards and may comprise finer lines and pitch, smaller vias and capture pads, as well as higher connection pad density. High density interconnects may thus be useful to reduce the size, thickness, weight, etc. of the package and/or device as well as enhancing electrical and thermal performance. The base portion 202 and the redistribution portion 204 may define an integrated device package base (e.g., package substrate) of the integrated device package 200.

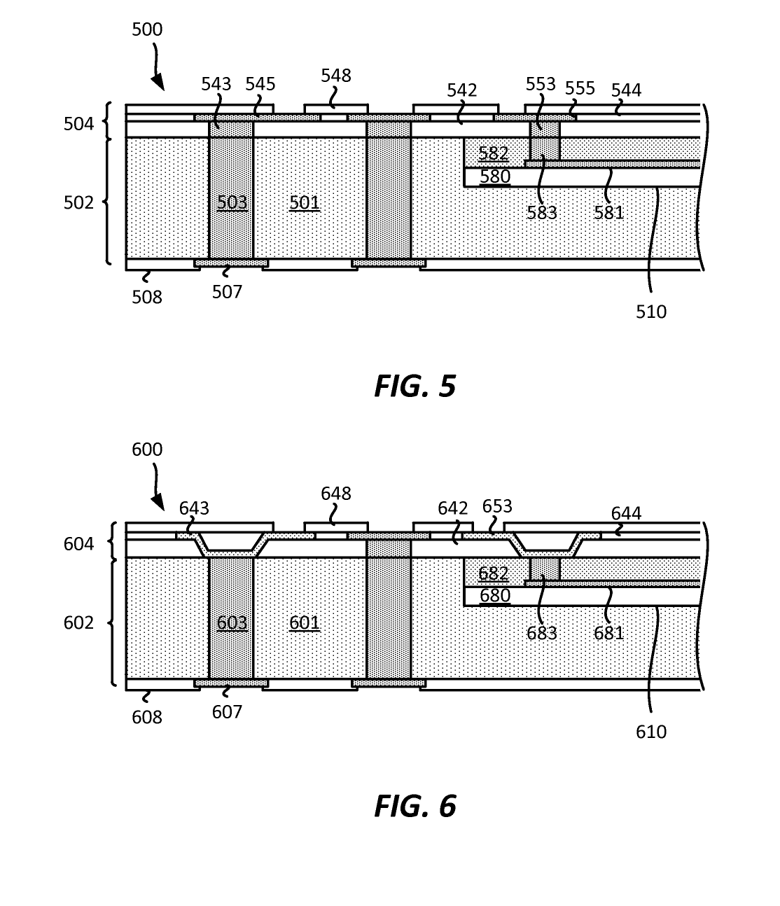

The base portion 202 includes a photo imageable layer 220, a set of vias 222, a set of pads 224, and a solder resist layer 226. In some implementations, the photo imageable layer 220 is a material that is photo etchable. That is, the photo imageable layer 220 is made of a material that can be etched and/or removed through the exposure of the material to a light source (e.g., ultraviolet (UV) light). The set of vias 222 vertically traverses the photo imageable layer 220. The set of pads 224 is coupled to the set of vias 222. The solder resist layer 226 covers a first surface (e.g., bottom surface) of the photo imageable layer 220. A first set of solder balls 230 is coupled to the first set of pads 224. In some implementations, the vias (e.g., vias 222) in the photo imageable layer 220 are vias that have a width/diameter of about 10 microns (μm) or less, and/or a spacing of about 10 microns (μm) or less. Examples of base portions are further described in detail in at least FIGS. 5-10.

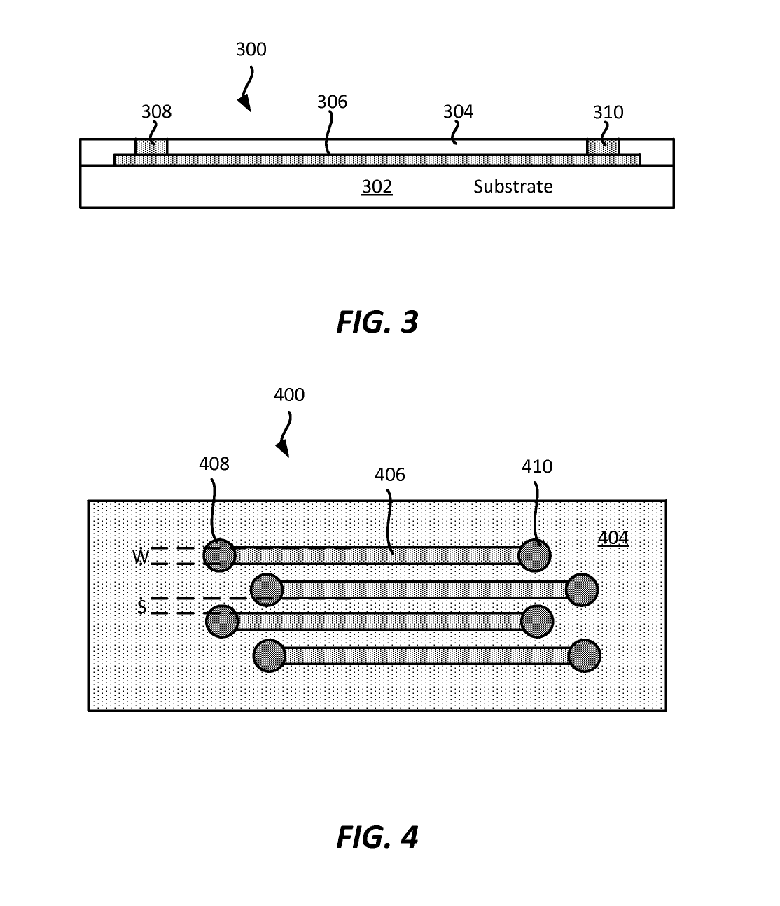

FIG. 2 illustrates that the silicon bridge 210 is at least partially embedded in the photo imageable layer 220 of the base portion 202. The silicon bridge 210 is configured to provide high density interconnects in the base portion 202. The silicon bridge 210 may include a substrate, a set of interconnects (e.g., set of high density interconnects), a set of vias, and a dielectric layer. In some implementations, the set of interconnects in the silicon bridge 210 has a higher density (e.g., density of interconnection) than the density of the set of vias 222 in the photo imageable layer 220. The density (e.g., density of interconnection) of a set of interconnects (e.g., vias) may refer to the width and/or spacing of the set of interconnects, which will be further described in FIGS. 3-4. An example of a bridge (e.g., silicon bridge) is also further described in detail in at least FIGS. 3-4.

The redistribution portion 204 includes a set of dielectric layers 240, and a set of interconnects 242. As shown in FIG. 2, the redistribution portion 204 is coupled to a second surface (e.g., top surface) of the base portion 202. The redistribution portion 204 is formed over a second surface (e.g., top surface) of the photo imageable layer 220 and the silicon bridge 210. The set of dielectric layers 240 may include one or more dielectric layers. The set of interconnects 242 may include traces, vias, pillars, posts, and/or pads. The set of interconnects 242 is coupled to the set of vias 222 and the silicon bridge 210. In some implementations, the set of interconnects 242 in the redistribution portion 204 are interconnects that have a width of about 5 microns (μm) or less, and/or a spacing of about 5 microns (μm) or less. Examples of various redistribution portions are further described in detail in at least FIGS. 5-10.

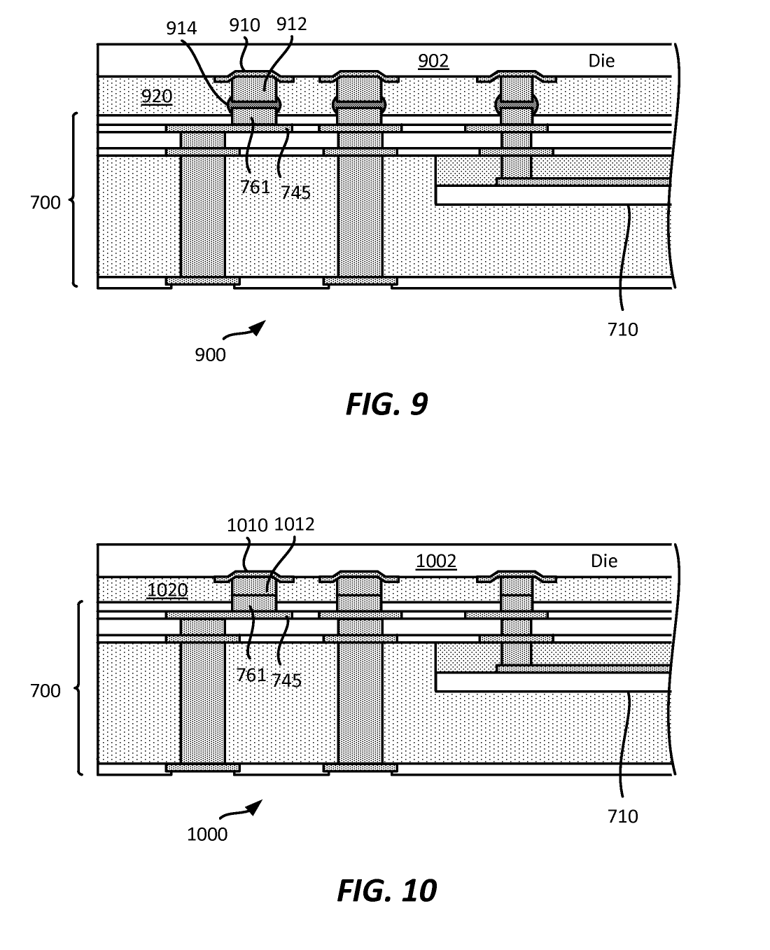

FIG. 2 illustrates that the first die 206 is coupled to the redistribution portion 204 through a set of interconnects 260. Similarly, the second die 208 is coupled to the redistribution portion 204 through a set of interconnects 280. The sets of interconnects 260 and 280 may include pillars, posts, and/or solder balls. The sets of interconnects 260 and 280 are coupled to the set of interconnects 242 of the redistribution portion 204. In some implementations, a fill 250 is located between the first die 206 and the redistribution portion 204. In some implementations, the fill 250 is located between the second die 208 and the redistribution portion 204. In some implementations, the implementations, the fill 250 is a non-conducting fill (NCF) or non-conducting paste (NCP). The fill 250 may at least partially surround the sets of interconnects 260 and/or 280. Examples of how a die may be coupled to the redistribution portion are further described in detail in at least FIGS. 9-10.

FIG. 2 further illustrates that the first die 206 may be electrically coupled to the second die 208. For example, in some implementations, the first die 206 may be electrically coupled to the second die 208 through the set of interconnects 260, a first set of interconnects from the set of interconnects 242, the bridge 210, a second set of interconnects from the set of interconnects 242, and/or the set of interconnects 280. In some implementations, the set of interconnects 260, the first set of interconnects from the set of interconnects 242, the bridge 210, the second set of interconnects from the set of interconnects 242, and/or the set of interconnects 280 define an electrical path for die-to-die connection between the first and second dies 206 and 208.

Although not shown, the integrated device package 200 may also include an encapsulation layer that covers the first and second dies 206 and 208, as well as the fill 250. The encapsulation layer may include one of at least a mold and/or an epoxy fill.

### Exemplary Silicon Bridge Comprising High Density Interconnects

As mentioned above, an integrated device may include a bridge (e.g., silicon bridge) that is configured to provide high density die-to-die interconnects. FIGS. 3 and 4 illustrate conceptual examples of such bridges configured to provide high density interconnects in an integrated device package.

FIG. 3 illustrates a profile view of an example of a bridge 300 (e.g., silicon bridge) that includes a substrate 302, a dielectric layer 304, a first interconnect 306, a second interconnect 308, and a third interconnect 310. In some implementations, the bridge 300 may be implemented in any of the integrated device package illustrated and described in the present disclosure. For example, the bridge 300 may be the silicon bridge 210 of FIG. 2. In some implementations, the bridge 300 is a bridge means configured to provide a die-to-die electrical path or die-to-die electrical connection between a first die and a second die. In some implementations, the bridge means provides a density interconnection that is equal or less than the density interconnection of the base portion (e.g., base portion 202) and/or the redistribution portion (e.g., redistribution portion 204) of an integrated device package base.

In some implementations, the substrate 302 is a silicon substrate and/or a wafer. The first interconnect 306 may be a trace located on the substrate 302. The dielectric layer 304 covers the first interconnect 306 and the substrate 302. In some implementations, the second and third interconnects 308 and 310 are vias that vertically traverses the dielectric layer 304. The second and third interconnects 308 and 310 are coupled to the first interconnect 306.

In some implementations, the first, second, and third interconnects 306, 308 and 310 are high density interconnects. In some implementations, high density interconnects are interconnects that have a width of about 2 microns (μm) or less, and/or a spacing of about 2 microns (μm) or less. In some implementations, the width of an interconnect may be the width of the trace and/or line. In some implementations, the width of an interconnect may be the diameter of a via and/or a pad. A spacing is an edge to edge distance between two neighboring/adjacent interconnects.

FIG. 4 illustrates a plan view (e.g., top view) of an example of a bridge 400 (e.g., silicon bridge) that includes a substrate (not visible), a dielectric layer 404, a first interconnect 406, a second interconnect 408, and a third interconnect 410. FIG. 4 illustrates the width and spacing of interconnects. The width of an interconnect is illustrated by (W), and the spacing between two neighboring/adjacent interconnects is illustrated by (S). In some implementations, the first, second, and third interconnects 406, 408, and 410 are high density interconnects. In some implementations, high density interconnects are interconnects that have a width of about 2 microns (μm) or less, and/or a spacing of about 2 microns (μm) or less.

### Exemplary Integrated Device Package Comprising Silicon Bridge in Photo Imageable Layer

Having described an example of an integrated device package that includes high density die-to-die interconnects in general detail, an example of an integrated device package that includes high density die-to-die interconnects will now be described in more detail.

FIG. 5 illustrates an example of a portion of integrated device package base 500 of an integrated device package. In some implementations, the integrated device package base 500 may correspond to at least the base portion 202 and the redistribution portion 204 of FIG. 2. In some implementations, the integrated device package base 500 is a package substrate of an integrated device package.

The integrated device package base 500 includes a base portion 502 and a redistribution portion 504. The base portion 502 includes a photo imageable layer 501, a via 503, a pad 507, a solder resist layer 508, and a bridge 510. In some implementations, the photo imageable layer 501 is a material that is photo etchable. That is, the photo imageable layer 501 is made of a material that can be etched and/or removed through the exposure of the material to a light source (e.g., ultraviolet (UV) light). The via 503 vertically traverses the photo imageable layer 501. The pad 507 is coupled to the via 503. The solder resist layer 508 covers a first surface (e.g., bottom surface) of the photo imageable layer 501. A solder ball may be coupled to the pad 507. The via 503 is part of a set of vias in the photo imageable layer 501, where the set of vias has a first density (e.g., first width and/or first spacing).

FIG. 5 also illustrates that the bridge 510 (e.g., a silicon bridge) is at least partially embedded in the photo imageable layer 501 of the base portion 502. The bridge 510 is configured to provide high density interconnects in the base portion 502. In some implementations, the bridge 510 is at least similar to the bridge of FIGS. 3-4. The bridge 510 includes a substrate 580 (e.g., a silicon substrate from a wafer), a dielectric layer 582, an interconnect 581, and an interconnect 583. The dielectric layer 582 may include one or more dielectric layers. In some implementations, the interconnects 581 and 583 may be high density interconnects, as described in FIGS. 3-4. In some implementations, high density interconnects are interconnects that have a width of about 2 microns (μm) or less, and/or a spacing of about 2 microns (μm) or less. In some implementations, the interconnects 581 and 583 have a second density (e.g., second width and/or second spacing) that is less than the first density of the via in the photo imageable layer 501.

The redistribution portion 504 is formed on the base portion 502 and the bridge 510. The redistribution portion 504 includes a first dielectric layer 542, a second dielectric layer 544, and a third dielectric layer 548, an interconnect 543, an interconnect 545, an interconnect 553, and an interconnect 555. In some implementations, the first, second, and/or third dielectric layers 542, 544, and/or 548 may be collectively a single dielectric layer. The interconnects 543 and 553 may be vias. The interconnects 545 and 555 may be traces and/or pads. In some implementations, the interconnects 545 and 555 may be configured to couple to interconnects (e.g., solder, pillar) from a die.

The interconnect 545 is coupled to the interconnect 543. The interconnect 543 of the redistribution portion 504 is coupled to the via 503 of the base portion 502. The interconnect 555 is coupled to the interconnect 553. The interconnect 553 of the redistribution portion 504 is coupled to the interconnect 583 of the bridge 510.

In some implementations, a first die (e.g., die 206) may be electrically coupled to a second die (e.g., second die 208) through the interconnect 555 (e.g., pad), the interconnect 553 (e.g., via), the interconnect 583 (e.g., via) and/or the interconnect 581 (e.g., trace). In some implementations, the interconnect 555 (e.g., pad), the interconnect 553 (e.g., via), the interconnect 583 (e.g., via) and/or the interconnect 581 (e.g., trace) define an electrical path for die-to-die connection between the first and second dies (e.g., dies 206 and 208).

### Exemplary Integrated Device Package Comprising Silicon Bridge in Photo Imageable Layer

FIG. 6 illustrates an example of a portion of integrated device package base 600 of an integrated device package. In some implementations, the integrated device package base 600 may correspond to at least the base portion 202 and the redistribution portion 204 of FIG. 2. In some implementations, the integrated device package base 600 is a package substrate of an integrated device package.

The integrated device package base 600 includes a base portion 602 and a redistribution portion 604. The base portion 602 includes a photo imageable layer 601, a via 603, a pad 607, a solder resist layer 608, and a bridge 610. In some implementations, the photo imageable layer 601 is a material that is photo etchable. That is, the photo imageable layer 601 is made of a material that can be etched and/or removed through the exposure of the material to a light source (e.g., ultraviolet (UV) light). The via 603 vertically traverses the photo imageable layer 601. The pad 607 is coupled to the via 603. The solder resist layer 608 covers a first surface (e.g., bottom surface) of the photo imageable layer 601. A solder ball may be coupled to the pad 607. The via 603 is part of a set of vias in the photo imageable layer 601, where the set of vias has a first density (e.g., first width and/or first spacing).

FIG. 6 also illustrates that the bridge 610 (e.g., silicon bridge) is at least partially embedded in the photo imageable layer 601 of the base portion 602. The bridge 610 is configured to provide high density interconnects in the base portion 602. In some implementations, the bridge 610 is at least similar to the bridge of FIGS. 3-4. The bridge 610 includes a substrate 680 (e.g., silicon substrate, wafer), a dielectric layer 682, an interconnect 681, and an interconnect 683. The dielectric layer 682 may include one or more dielectric layers. In some implementations, the interconnects 681 and 683 may be high density interconnects, as described in FIGS. 3-4. In some implementations, high density interconnects are interconnects that have a width of about 2 microns (μm) or less, and/or a spacing of about 2 microns (μm) or less. In some implementations, the interconnects 681 and 683 have a second density (e.g., second width and/or second spacing) that is less than the first density of the via in the photo imageable layer 601.

The redistribution portion 604 is formed on the base portion 602 and the bridge 610. The redistribution portion 604 includes a first dielectric layer 642, a second dielectric layer 644, and a third dielectric layer 648, an interconnect 643, and an interconnect 653. In some implementations, the first, second, and/or third dielectric layers 642, 644, and/or 648 may be collectively a single dielectric layer. The interconnects 643 and 653 may be a redistribution interconnect. In some implementations, the interconnects 643 and 653 may be configured to couple to interconnects (e.g., solder, pillar) from a die.

The interconnect 643 of the redistribution portion 604 is coupled to the via 603 of the base portion 602. The interconnect 653 of the redistribution portion 604 is coupled to the interconnect 683 of the bridge 610.

In some implementations, a first die (e.g., die 206) may be electrically coupled to a second die (e.g., second die 208) through the interconnect 653 (e.g., redistribution interconnect), the interconnect 683 (e.g., via) and/or the interconnect 681 (e.g., trace). In some implementations, the interconnect 653 (e.g., redistribution interconnect), the interconnect 683 (e.g., via) and/or the interconnect 681 (e.g., trace) define an electrical path for die-to-die connection between the first and second dies (e.g., dies 206 and 208).

### Exemplary Integrated Device Package Comprising Silicon Bridge in Photo Imageable Layer

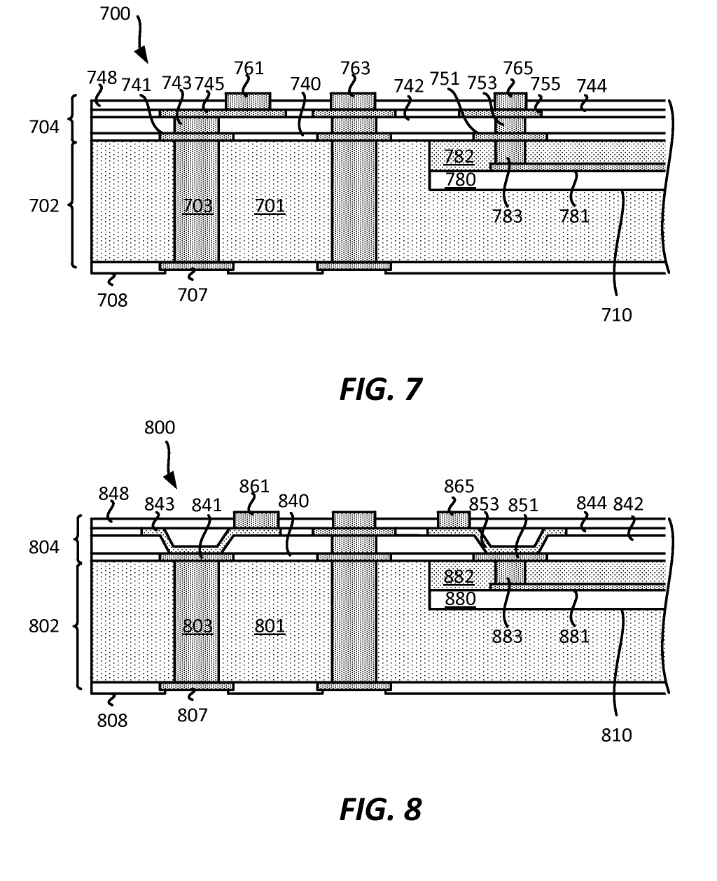

FIG. 7 illustrates an example of a portion of an integrated device package base 700 of an integrated device package. In some implementations, the integrated device package base 700 may correspond to at least the base portion 202 and the redistribution portion 204 of FIG. 2. In some implementations, the integrated device package base 700 is a package substrate of an integrated device package.

The integrated device package base 700 includes a base portion 702 and a redistribution portion 704. The base portion 702 includes a photo imageable layer 701, a via 703, a pad 707, a solder resist layer 708, and a bridge 710. In some implementations, the photo imageable layer 701 is a material that is photo etchable. That is, the photo imageable layer 701 is made of a material that can be etched and/or removed through the exposure of the material to a light source (e.g., ultraviolet (UV) light). The via 703 vertically traverses the photo imageable layer 701. The pad 707 is coupled to the via 703. The solder resist layer 708 covers a first surface (e.g., bottom surface) of the photo imageable layer 701. A solder ball may be coupled to the pad 707. The via 703 is part of a set of vias in the photo imageable layer 701, where the set of vias has a first density (e.g., first width and/or first spacing).

FIG. 7 also illustrates that the bridge 710 (e.g., silicon bridge) is at least partially embedded in the photo imageable layer 701 of the base portion 702. The bridge 710 is configured to provide high density interconnects in the base portion 702. In some implementations, the bridge 710 is at least similar to the bridge of FIGS. 3-4. The bridge 710 includes a substrate 780 (e.g., silicon substrate, wafer), a dielectric layer 782, an interconnect 781, and an interconnect 783. The dielectric layer 782 may include one or more dielectric layers. In some implementations, the interconnects 781 and 783 may be high density interconnects, as described in FIGS. 3-4. In some implementations, high density interconnects are interconnects that have a width of about 2 microns (μm) or less, and/or a spacing of about 2 microns (μm) or less. In some implementations, the interconnects 781 and 783 have a second density (e.g., second width and/or second spacing) that is less than the first density of the via in the photo imageable layer 701.

The redistribution portion 704 is formed on the base portion 702 and the bridge 710. The redistribution portion 704 includes a first dielectric layer 742, a second dielectric layer 744, and a third dielectric layer 748, an interconnect 741, an interconnect 743, an interconnect 745, an interconnect 751, an interconnect 753, an interconnect 755, an interconnect 761, and an interconnect 765. In some implementations, the first, second, and/or third dielectric layers 742, 744, and/or 748 may be collectively a single dielectric layer. The interconnects 741 and 751 may be pads. The interconnects 743 and 753 may be vias. The interconnects 745 and 755 may be traces and/or pads. The interconnects 761 and 765 may be pillars and/or traces. In some implementations, the interconnects 761 and 765 may be configured to couple to interconnects (e.g., solder, pillar) from a die.

The interconnect 761 is coupled to the interconnect 745. The interconnect 745 is coupled to the interconnect 743. The interconnect 743 is coupled to the interconnect 741. The interconnect 741 of the redistribution portion 704 is coupled to the via 703 of the base portion 702. The interconnect 765 is coupled to the interconnect 755. The interconnect 755 is coupled to the interconnect 753. The interconnect 753 is coupled to the interconnect 751. The interconnect 751 of the redistribution portion 704 is coupled to the interconnect 783 of the bridge 710.

In some implementations, a first die (e.g., die 206) may be electrically coupled to a second die (e.g., second die 208) through the interconnect 765, the interconnect 755 (e.g., pad), the interconnect 753 (e.g., via), the interconnect 751 (e.g., pad), the interconnect 783 (e.g., via) and/or the interconnect 781 (e.g., trace). In some implementations, the interconnect 765, the interconnect 755 (e.g., pad), the interconnect 753 (e.g., via), the interconnect 751 (e.g., pad), the interconnect 783 (e.g., via) and/or the interconnect 781 (e.g., trace) define an electrical path for die-to-die connection between the first and second dies (e.g., dies 206 and 208).

### Exemplary Integrated Device Package Comprising Silicon Bridge in Photo Imageable Layer

FIG. 8 illustrates an example of a portion of integrated device package base 800 of an integrated device package. In some implementations, the integrated device package base 800 may correspond to at least the base portion 202 and the redistribution portion 204 of FIG. 2. In some implementations, the integrated device package base 800 is a package substrate of an integrated device package.

The integrated device package base 800 includes a base portion 802 and a redistribution portion 804. The base portion 802 includes a photo imageable layer 801, a via 803, a pad 807, a solder resist layer 808, and a bridge 810. In some implementations, the photo imageable layer 801 is a material that is photo etchable. That is, the photo imageable layer 801 is made of a material that can be etched and/or removed through the exposure of the material to a light source (e.g., ultraviolet (UV) light). The via 803 vertically traverses the photo imageable layer 801. The pad 807 is coupled to the via 803. The solder resist layer 808 covers a first surface (e.g., bottom surface) of the photo imageable layer 801. A solder ball may be coupled to the pad 807. The via 803 is part of a set of vias in the photo imageable layer 801, where the set of vias has a first density (e.g., first width and/or first spacing).

FIG. 8 also illustrates that the bridge 810 (e.g., silicon bridge) is at least partially embedded in the photo imageable layer 801 of the base portion 802. The bridge 810 is configured to provide high density interconnects in the base portion 802. In some implementations, the bridge 810 is at least similar to the bridge of FIGS. 3-4. The bridge 810 includes a substrate 880 (e.g., silicon substrate, wafer), a dielectric layer 882, an interconnect 881, and an interconnect 883. The dielectric layer 882 may include one or more dielectric layers. In some implementations, the interconnects 881 and 883 may be high density interconnects, as described in FIGS. 3-4. In some implementations, high density interconnects are interconnects that have a width of about 2 microns (μm) or less, and/or a spacing of about 2 microns (μm) or less. In some implementations, the interconnects 881 and 883 have a second density (e.g., second width and/or second spacing) that is less than the first density of the via in the photo imageable layer 801.

The redistribution portion 804 is formed on the base portion 802 and the bridge 810. The redistribution portion 804 includes a first dielectric layer 842, a second dielectric layer 844, and a third dielectric layer 848, an interconnect 841, an interconnect 843, an interconnect 851, an interconnect 853, an interconnect 861, and an interconnect 865. In some implementations, the first, second, and/or third dielectric layers 842, 844, and/or 848 may be collectively a single dielectric layer. The interconnects 841 and 851 may be pads. The interconnects 843 and 853 may be a redistribution interconnect. The interconnects 861 and 865 may be pillars and/or traces. In some implementations, the interconnects 861 and 865 may be configured to couple to interconnects (e.g., solder, pillar) from a die.

The interconnect 861 is coupled to the interconnect 843. The interconnect 843 is coupled to the interconnect 841. The interconnect 841 of the redistribution portion 804 is coupled to the via 803 of the base portion 802. The interconnect 865 is coupled to the interconnect 853. The interconnect 853 is coupled to the interconnect 851. The interconnect 851 of the redistribution portion 804 is coupled to the interconnect 883 of the bridge 810.

In some implementations, a first die (e.g., die 206) may be electrically coupled to a second die (e.g., second die 208) through the interconnect 865, the interconnect 853 (e.g., redistribution interconnect), the interconnect 851 (e.g., pad), the interconnect 883 (e.g., via) and/or the interconnect 881 (e.g., trace). In some implementations, the interconnect 865, the interconnect 855 (e.g., pad), the interconnect 853 (e.g., via), the interconnect 851 (e.g., pad), the interconnect 883 (e.g., via) and/or the interconnect 881 (e.g., trace) define an electrical path for die-to-die connection between the first and second dies (e.g., dies 206 and 208).

### Exemplary Integrated Device Packages Comprising Silicon Bridge in Photo Imageable Layer

FIG. 9 illustrates an example of an integrated device package 900 that includes a die coupled to an integrated device package base. As shown in FIG. 9, the integrated device package 900 includes a die 902 that is coupled to the integrated device package base 700. It should be noted that the die 902 may be coupled to any of the integrated device package base described in the present disclosure (e.g., integrated device package bases 500, 600, 800). The die 902 includes a under bump metallization (UBM) layer 910, a pillar 912, and solder 914. The die 902 is coupled to the integrated device package base 700 through the UBM layer 910 (optional), the pillar 912, the solder 914, the interconnect 761 (optional), and the interconnect 745 of the integrated device package base 700. As further shown, a fill 920 is located between the die 902 and the integrated device package base 700. The fill 920 may include one of at least a non-conducting fill (NCF) and/or non-conducting paste (NCP). The fill 920 covers the interconnects (e.g., pillar 912, solder 914, interconnect 761) between the die 902 and the integrated device package base 700.

FIG. 10 illustrates another example of an integrated device package 1000 that includes a die coupled to an integrated device package base. As shown in FIG. 10, the integrated device package 1000 includes a die 1002 that is coupled to the integrated device package base 700. It should be noted that the die 1002 may be coupled to any of the integrated device package base described in the present disclosure (e.g., integrated device package bases 500, 600, 800). The die 1002 includes a under bump metallization (UBM) layer 1010, a pillar 1012. The die 1002 is coupled to the integrated device package base 700 through the UBM layer 1010 (optional), the pillar 1012, the interconnect 761, and the interconnect 745 of the integrated device package base 700. As further shown, a fill 1020 is located between the die 1002 and the integrated device package base 700. The fill 1020 may include one of at least a non-conducting fill (NCF) and/or non-conducting paste (NCP). The fill 1020 covers the interconnects (e.g., pillar 1012, interconnect 761) between the die 1002 and the integrated device package base 700. In some implementations, instead of an interconnect 761, a solder may exist between the pillar 1012 and the interconnect 745.

### Exemplary Sequence for Providing/Fabricating a High Density Interconnect Silicon Bridge

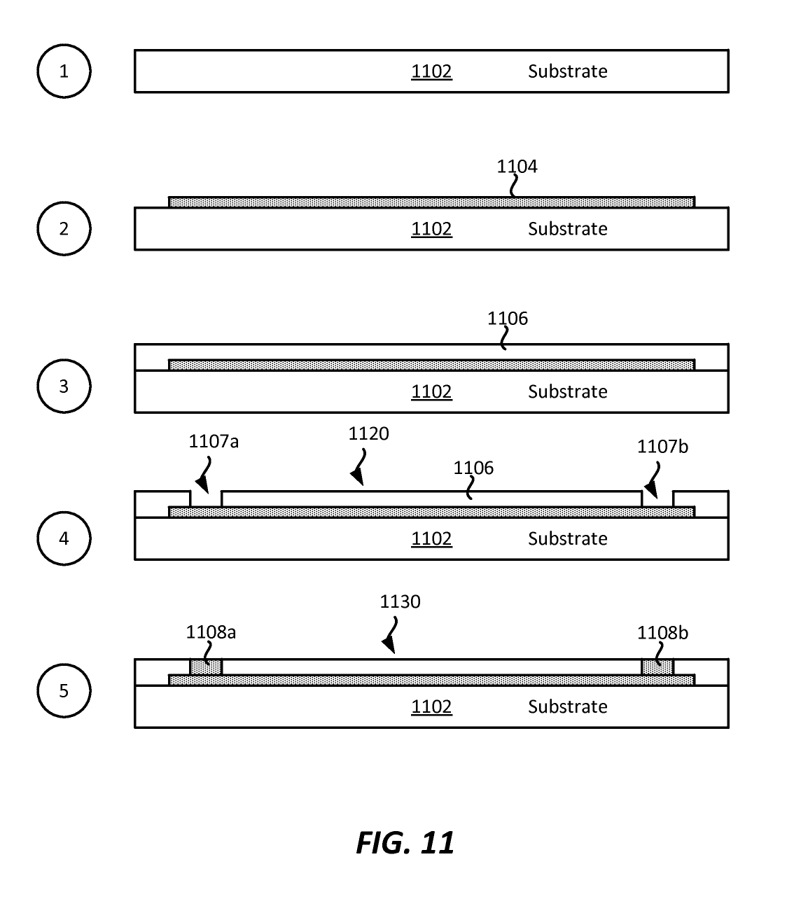

In some implementations, providing/fabricating a high density interconnect silicon bridge includes several processes. FIG. 11 illustrates an exemplary sequence for providing/fabricating a high density interconnect silicon bridge. In some implementations, the sequence of FIG. 11 may be used to provide/fabricate the bridge of FIGS. 2-10 and/or other bridges described in the present disclosure. However, for the purpose of simplification, FIG. 11 will be described in the context of providing/fabricating the bridge of FIG. 3.

It should be noted that the sequence of FIG. 11 may combine one or more stages in order to simplify and/or clarify the sequence for providing/fabricating a bridge. In some implementations, the order of the processes may be changed or modified.

Stage 1 of FIG. 11, illustrates a state after a substrate 1102 is provided. In some implementations, the substrate 1102 is provided by a supplier. In some implementations, the substrate 1102 is fabricated (e.g., formed). In some implementations, the substrate 1102 is one of at least a silicon substrate and/or wafer (e.g., silicon wafer).

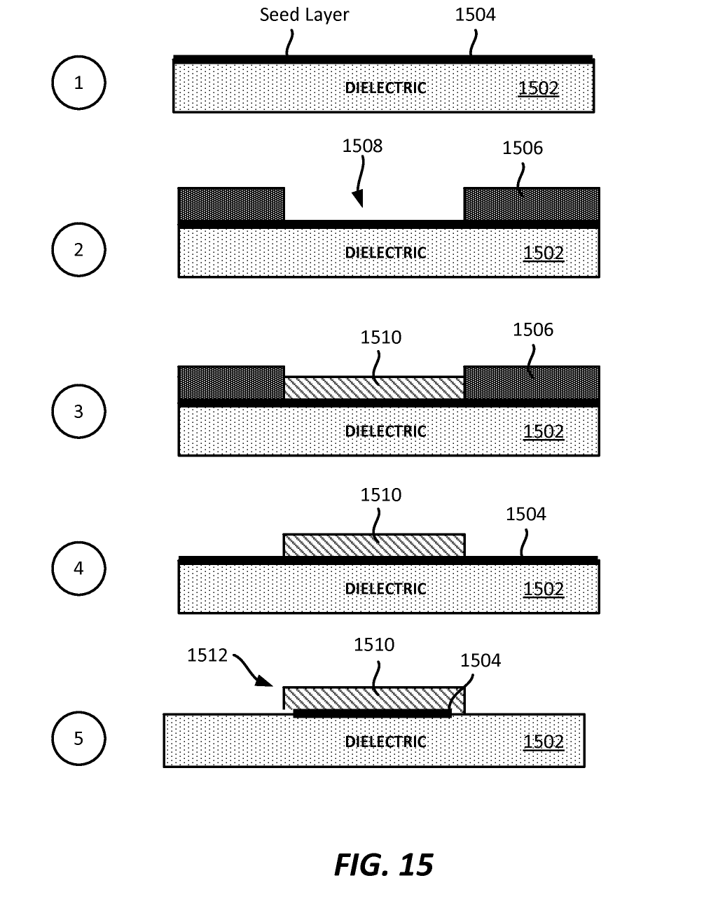

Stage 2 illustrates a state after a metal layer 1104 is formed on the substrate 1102. In some implementations, the metal layer 1104 may form and/or define one or more high density interconnects (e.g., as described in FIGS. 3-4). In some implementations, providing the metal layer 1104 includes forming (e.g., plating) one or more metal layers (e.g., seed layer and metal layer) and selectively etching portions of the one or more metal layers. FIGS. 15-18 illustrate examples of providing one or more metal layers using several plating processes.

Stage 3 illustrates a state after a dielectric layer 1106 is formed over the substrate 1102 and the metal layer 1104. Different implementations may use different materials for the dielectric layer 1106.

Stage 4 illustrates a state after cavities 1107 (e.g., cavity 1107a, cavity 1107b) are formed in the dielectric layer 1106. Different implementations may use different processes for forming cavities in the dielectric layer 1106. In some implementations, a laser may be used to form the cavities. In some implementations, a photo etching process is used to form the cavities. In some implementations, the stage 4 illustrates a bridge 1120 (e.g., silicon bridge) that may be implemented in a photo imageable layer of any of the base portion (e.g., package substrate) described in the present disclosure.

Stage 5 illustrates a state after vias 1108 (e.g., via 1108a, via 1108b) are formed in the dielectric layer 1106. Specifically, the vias 1108 are formed in the cavities 1107 of the dielectric layer 1106. In some implementations, the vias 1108 are high density vias (e.g., as described in FIGS. 3-4). In some implementations, the vias 1108 are metal layer(s) that are formed using one or more plating processes. FIGS. 15-18 illustrate examples of providing one or more metal layers using several plating processes. In some implementations, the stage 5 illustrates a bridge 1130 (e.g., silicon bridge) that may be implemented in a photo imageable layer of any of the base portion described in the present disclosure. It should be noted that in some implementations, the vias 1108 may be formed once the bridge is positioned or embedded in a photo imageable layer of the base portion.

### Exemplary Flow Diagram of a Method for Providing/Fabricating a High Density Interconnect Silicon Bridge

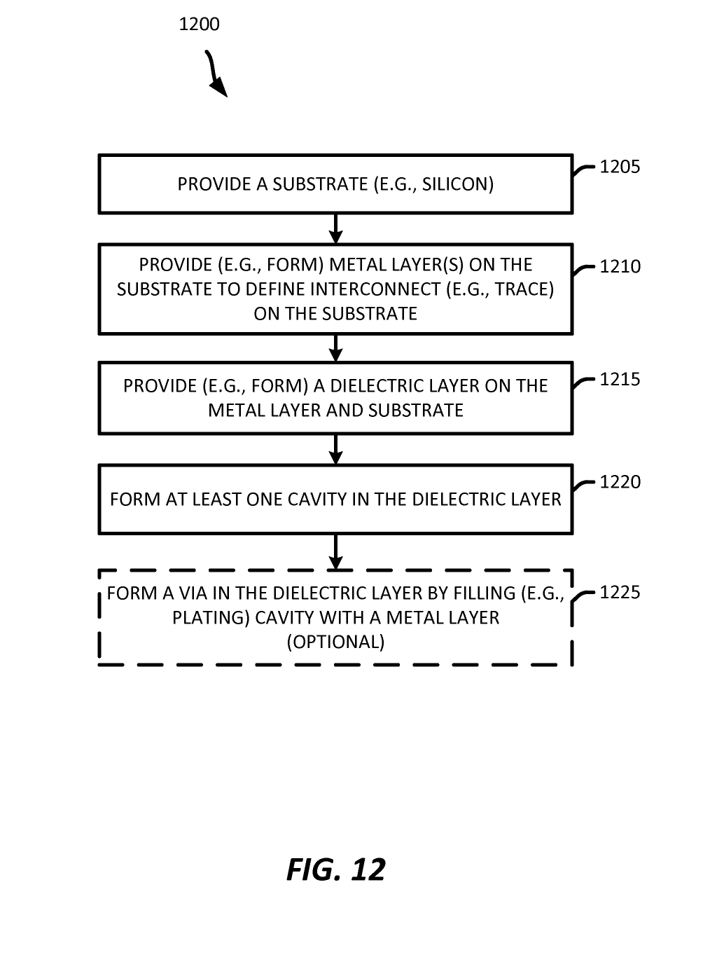

FIG. 12 illustrates an exemplary flow diagram for providing/fabricating a high density interconnect silicon bridge. In some implementations, the method of FIG. 12 may be used to provide/fabricate the high density interconnect silicon bridge of FIGS. 2-10 and/or other high density interconnect silicon bridge in the present disclosure.

It should be noted that the flow diagram of FIG. 12 may combine one or more step and/or processes in order to simplify and/or clarify the method for providing a passive device package. In some implementations, the order of the processes may be changed or modified.

The method provides (at 1205) a substrate. In some implementations, providing the substrate may includes receiving a substrate from a supplier or fabricating (e.g., forming) a substrate. In some implementations, the substrate is one of at least a silicon substrate and/or wafer (e.g., silicon wafer).

The method forms (at 1210) a metal layer on the substrate to form one or more high density interconnect (e.g., as described in FIGS. 3-4). In some implementations, forming the metal layer includes forming (e.g., plating) one or more metal layers (e.g., seed layer and metal layer) and selectively etching portions of the one or more metal layers. FIGS. 15-18 illustrate examples of providing one or more metal layers using several plating processes.

The method forms (at 1215) a dielectric layer over the substrate and the metal layer. Different implementations may use different materials for the dielectric layer.

The method then forms (at 1220) at least one cavity in the dielectric layer. Different implementations may use different processes for forming cavities in the dielectric layer. In some implementations, a laser may be used to form the cavities. In some implementations, a photo etching process is used to form the cavities. In some implementations, once the cavity is formed, a bridge (e.g., bridge 1120) may be defined which may be implemented in a photo imageable layer of any of the base portion (e.g., package substrate) described in the present disclosure.

The method optionally forms (at 1225) a via in the dielectric layer. Specifically, the method fills the cavity of the dielectric layer with one or more conducting material (e.g., metal layers) to form a via in the cavity. In some implementations, the vias are high density vias (e.g., as described in FIGS. 3-4). In some implementations, the vias are metal layer(s) that are formed using one or more plating processes. FIGS. 15-18 illustrate examples of providing one or more metal layers using several plating processes. It should be noted that in some implementations, the vias may be formed once the bridge is positioned or embedded in a photo imageable layer of the base portion.

Exemplary Sequence for Providing/Fabricating an Integrated Device Package that Includes a High Density Interconnect Silicon Bridge in a Photo Imageable Layer

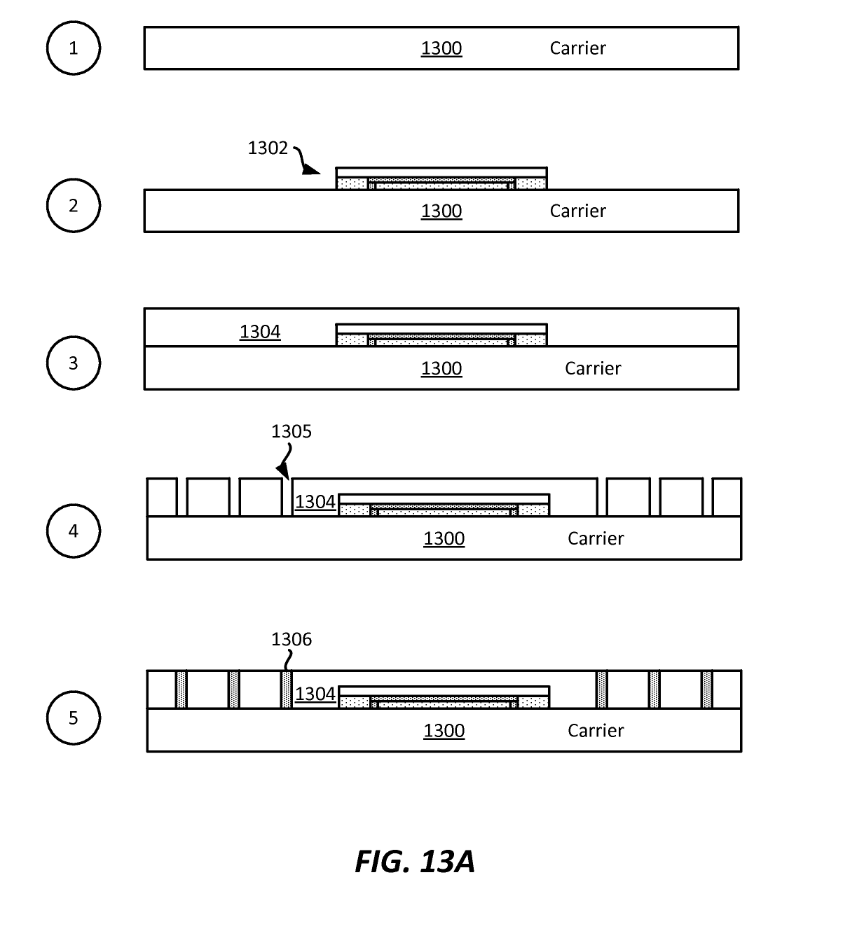

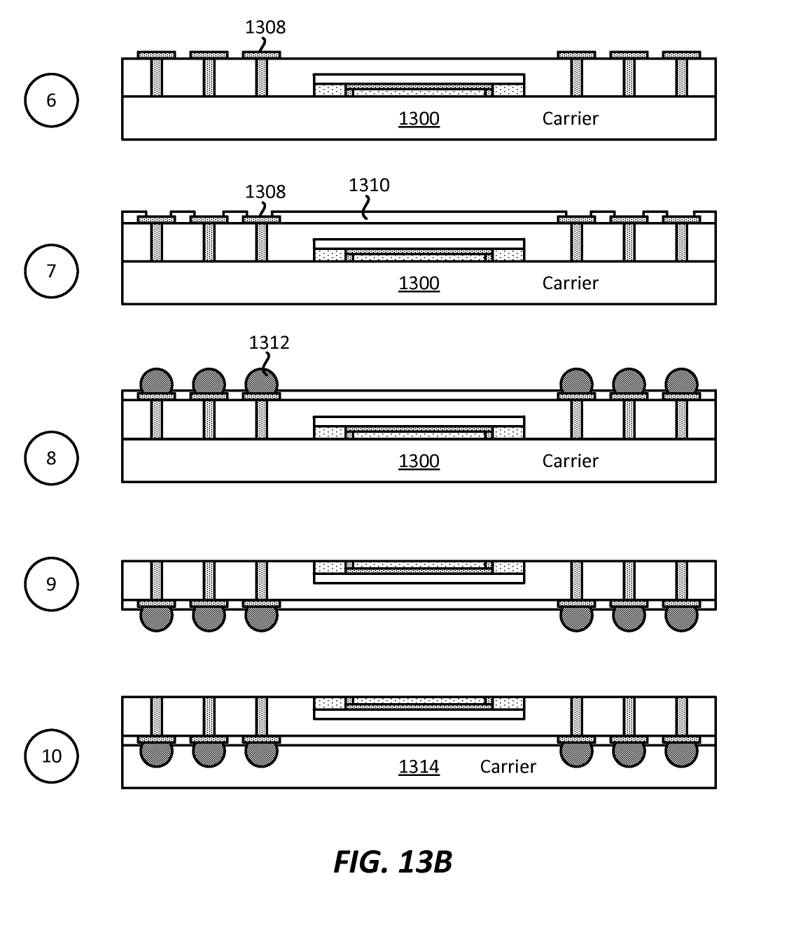

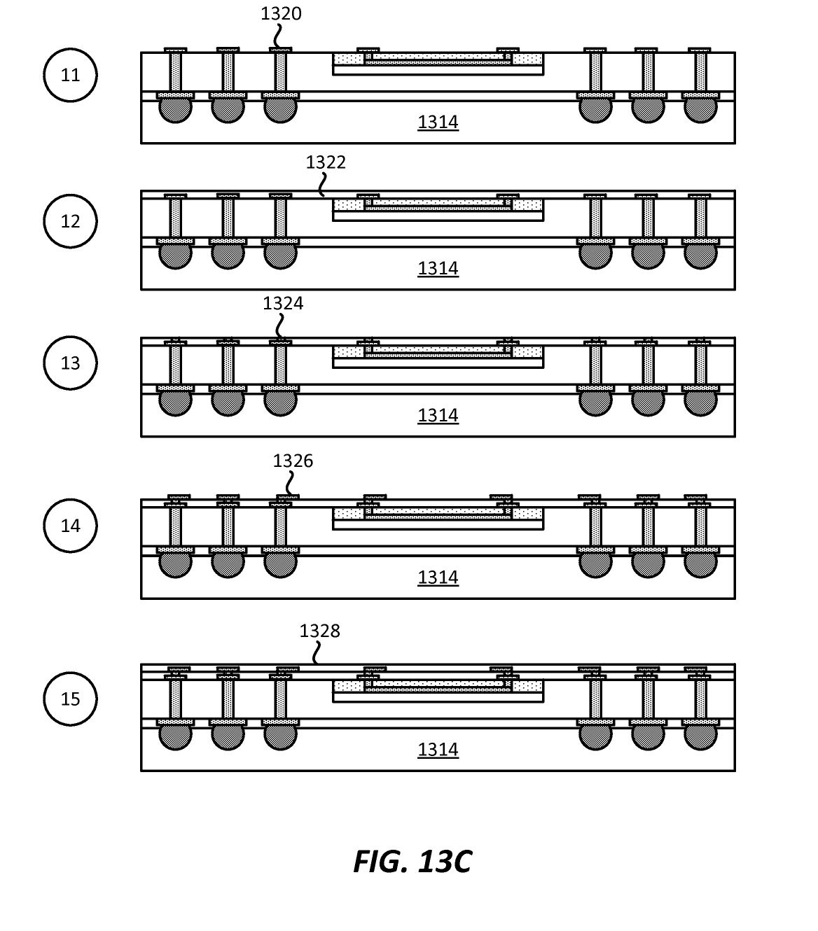

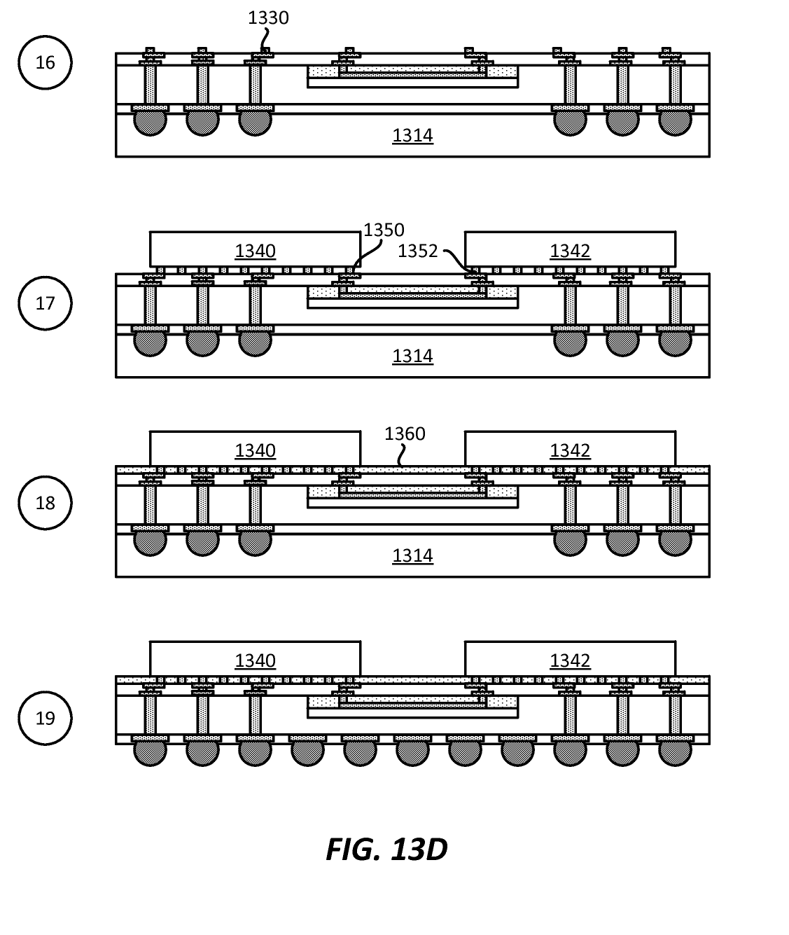

In some implementations, providing/fabricating an integrated device package that includes a high density interconnect silicon bridge in a photo imageable layer includes several processes. FIG. 13 (which includes FIGS. 13A-13D) illustrates an exemplary sequence for providing/fabricating an integrated device package that includes a high density interconnect silicon bridge in a photo imageable layer. In some implementations, the sequence of FIGS. 13A-13D may be used to provide/fabricate the integrated device package of FIGS. 2, 5-10 and/or other integrated device packages in the present disclosure. However, for the purpose of simplification, FIGS. 13A-13D will be described in the context of providing/fabricating the integrated device package of FIG. 2.

It should be noted that the sequence of FIGS. 13A-13D may combine one or more stages in order to simplify and/or clarify the sequence for providing an integrated device package. In some implementations, the order of the processes may be changed or modified.

Stage 1 of FIG. 13A, illustrates a state after a carrier 1300 is provided. In some implementations, the carrier 1300 is provided by a supplier. In some implementations, the carrier 1300 is fabricated (e.g., formed). In some implementations, the carrier 1300 is a silicon substrate and/or wafer (e.g., silicon wafer).

Stage 2 illustrates a state after a bridge 1302 is provided. The bridge 1302 may include a substrate, at least one metal layer, at least one via, and/or at least one dielectric layer, as described in FIG. 3. Examples of the bridge 1302 include the bridge shown and described in FIGS. 3-4. In some implementations, the bridge 1302 is a high density interconnect bridge configured to provide a connection and/or electrical path between two dies. As shown at stage 2, the bridge 1302 is coupled to a surface of the carrier 1300. In some implementations, an adhesive is used to mechanically couple the bridge 1302 to the carrier 1300.

Stage 3 illustrates a state after a photo imageable layer 1304 is provided on the carrier 1300 and the bridge 1302. The photo imageable layer 1304 may be a photo imageable dielectric layer. The photo imageable layer 1304 covers at the least bridge 1302.

Stage 4 illustrates a state after at least one cavity 1305 is formed in the photo imageable layer 1304. The at least one cavity 1305 is removed by using a photo etching process that selectively removes portions of the photo imageable layer 1304 by selectively exposing the photo imageable layer 1304 to a light source (e.g., UV light).

Stage 5 illustrates a state after at least one via 1306 is formed in the photo imageable layer 1304. Specifically, the via 1306 is formed in the cavity 1305 of the photo imageable layer 1304. In some implementations, the via 1306 is metal layer(s) that are formed using one or more plating processes. FIGS. 15-18 illustrate examples of providing one or more metal layers using several plating processes.

Stage 6, as shown in FIG. 13B, a first metal layer 1308 is formed on a first surface of the photo imageable layer 1304 and/or via 1306. The first metal layer 1308 may be configured to define one or more pads on the photo imageable layer 1304. In some implementations, providing the first metal layer 1308 includes forming (e.g., plating) one or more metal layers (e.g., seed layer and metal layer) and selectively etching portions of the one or more metal layers. FIGS. 15-18 illustrate examples of providing one or more metal layers using several plating processes.

Stage 7 illustrates a state after a solder resist layer 1310 is formed over the photo imageable layer 1304. As shown at stage 7, at least some portions of the first metal layer 1308 (e.g., pads) may be exposed and/or free of the solder resist layer 1310.

Stage 8 illustrates a state after a set of solder balls 1312 is provided on the first metal layer 1308 (e.g., on the pads).

Stage 9 illustrates a state after the carrier 1300 is removed. Different implementations may remove the carrier 1300 differently. In some implementations, the carrier 1300 is detached from the bridge 1302 and the photo imageable layer 1304. In some implementations, the carrier 1300 is removed through an etching process.

Stage 10 illustrates a state after the bridge 1302, the photo imageable layer 1304, the solder resist layer 1310, and the solder balls 1312 are mechanically coupled to a second carrier 1314. In some implementations, the second carrier 1314 is a carrier film. As shown at stage 10, the solder resist layer 1310 and the solder balls 1312 is coupled to the second carrier 1314.

Stage 11, as shown in FIG. 13C, illustrates a state after a metal layer 1320 is formed on a second surface of the photo imageable layer 1304. The metal layer 1320 may be configured to define one or more pads on the photo imageable layer 1304. In some implementations, the metal layer 1320 defines a redistribution layer in a redistribution portion. In some implementations, providing the metal layer 1320 includes forming (e.g., plating) one or more metal layers (e.g., seed layer and metal layer) and selectively etching portions of the one or more metal layers. FIGS. 15-18 illustrate examples of providing one or more metal layers using several plating processes.

Stage 12 illustrates a state after a first dielectric layer 1322 is provided (e.g., formed) on the bridge 1302, the second surface of the photo imageable layer 1304, and the metal layer 1320.

Stage 13 illustrates a state after at least one via 1324 is formed in the first dielectric layer 1322. In some implementations, the via 1324 is formed by forming a cavity in the first dielectric layer 1322 and filling the cavity to form the via 1324. Thus, in some implementations, portions of the first dielectric layer 1322 are selectively removed (e.g., etched) to form one or more cavities in the first dielectric layer 1322, and the cavities are filled to form the via 1324. In some implementations, the via 1324 is an interconnect in a redistribution portion.

Stage 14 illustrates a state after a metal layer 1326 is formed on the first dielectric layer 1322. The metal layer 1326 may be configured to define one or more traces and/or pads on the first dielectric layer 1322. In some implementations, the metal layer 1326 defines a redistribution layer in a redistribution portion. In some implementations, providing the metal layer 1326 includes forming (e.g., plating) one or more metal layers (e.g., seed layer and metal layer) and selectively etching portions of the one or more metal layers. FIGS. 15-18 illustrate examples of providing one or more metal layers using several plating processes.

Stage 15 illustrates a state after a second dielectric layer 1328 is provided (e.g., formed) on the first dielectric layer 1322.

Stage 16, as shown in FIG. 13D, illustrates a state after a metal layer 1330 is formed on the second dielectric layer 1328. The metal layer 1330 may be configured to define one or more pillars, traces and/or pads on the second dielectric layer 1328. In some implementations, providing the metal layer 1330 includes forming (e.g., plating) one or more metal layers (e.g., seed layer and metal layer) and selectively etching portions of the one or more metal layers. FIGS. 15-18 illustrate examples of providing one or more metal layers using several plating processes.

Stage 17 illustrates a state after a first die 1340 and a second die 1342 is provided on the redistribution portion. Specifically, the first die 1340 is coupled to the interconnects in the redistribution portion through the set of interconnects 1350. The set of interconnects 1350 may includes at least a pillar and/or solder. The second die 1342 is coupled to the interconnects in the redistribution portion through the set of interconnects 1352.

Stage 18 illustrates a state after a fill 1360 is formed between the dies 1340-1342 and the redistribution portion (e.g., second dielectric layer 1328). The fill 1360 may include a non-conducting fill (NCF) and/or a non-conducting paste (NCP).

Stage 19 illustrates a state after the second carrier 1314 is removed or decoupled from the solder resist layer 1310 and the solder balls 1312, leaving a package base that includes a high interconnect bridge in a photo imageable layer (e.g., as described in FIG. 2).

Exemplary Method for Providing/Fabricating an Integrated Device Package that Includes a High Density Interconnect Silicon Bridge in a Photo Imageable Layer

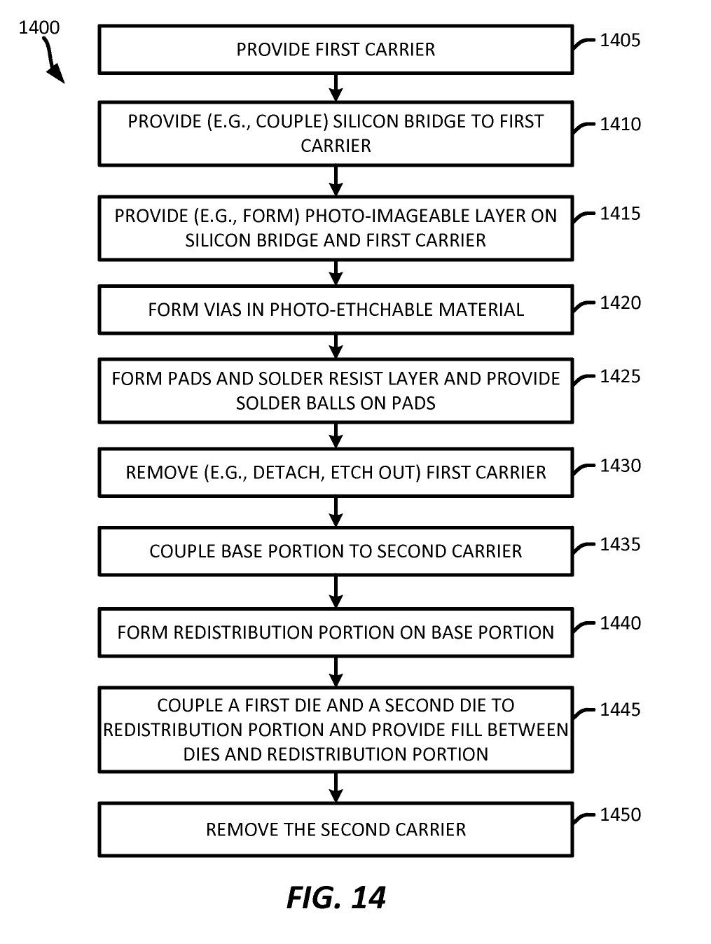

FIG. 14 illustrates an exemplary flow diagram of a method for providing/fabricating an integrated device package that includes a high density interconnect silicon bridge in a photo imageable layer. In some implementations, the method of FIG. 14 may be used to provide/fabricate the integrated device package of FIG. 2 and/or other integrated device in the present disclosure.

It should be noted that the flow diagram of FIG. 14 may combine one or more step and/or processes in order to simplify and/or clarify the method for providing an integrated device package. In some implementations, the order of the processes may be changed or modified.

The method provides (at 1405) a carrier. In some implementations, the carrier is provided by a supplier. In some implementations, the carrier is fabricated (e.g., formed). In some implementations, the carrier is a silicon substrate and/or wafer (e.g., silicon wafer).

The method then couples (at 1410) a bridge to the carrier. The bridge may include a substrate, at least one metal layer, at least one via, and/or at least one dielectric layer, as described in FIG. 3. In some implementations, the bridge is a high density interconnect bridge configured to provide a connection and/or electrical path between two dies. In some implementations, an adhesive is used to mechanically couple the bridge to the carrier.

The method forms (at 1415) a photo imageable layer on the carrier and the bridge. The photo imageable layer may be a photo imageable dielectric layer. The photo imageable layer covers at the least bridge.

The method forms (at 1420) at least one via in the photo imageable layer. In some implementations, forming the via includes forming at least one cavity in the photo imageable layer by using a photo etching process that selectively removes portions of the photo imageable layer 1304 (e.g., by selectively exposing the photo imageable layer to a light source (e.g., UV light)). The method then fills the cavity with one or more metal layers. In some implementations, the via is metal layer(s) that are formed using one or more plating processes. FIGS. 15-18 illustrate examples of providing one or more metal layers using several plating processes.

The method forms (at 1425) pads and a solder resist layer on the photo imageable layer. In some implementations, providing the pads includes forming (e.g., plating) one or more metal layers (e.g., seed layer and metal layer) and selectively etching portions of the one or more metal layers to define the pads. FIGS. 15-18 illustrate examples of providing one or more metal layers using several plating processes. The method also provides (at 1425) solder balls on the pads.

The method then removes (at 1430) the first carrier, leaving a base portion comprising the photo imageable layer, the bridge, the via, the pads, the solder resist layer, and the solder balls. Different implementations may remove the first carrier differently. In some implementations, the first carrier is decoupled from the bridge and photo imageable layer. In some implementations, the first carrier is etched out.

The method then couples (at 1435) the remaining base portion to a second carrier. In some implementations, the second carrier is a carrier film. The side of the base portion comprising the solder ball and solder resist layer is coupled to the second carrier.

The method forms (at 1440) a redistribution portion on the base portion. Specifically, the redistribution portion is formed on the side of the base portion where the bridge is exposed. In some implementations, forming the redistribution portion includes form at least one dielectric layer, and at least one metal layer. The one metal layer may define one or more interconnects (e.g., pads, traces, vias, posts, pillars, redistribution interconnects). In some implementations, providing the metal layer includes forming (e.g., plating) one or more metal layers (e.g., seed layer and metal layer) and selectively etching portions of the one or more metal layers. FIGS. 15-18 illustrate examples of providing one or more metal layers using several plating processes.

The method then couples (at 1445) a first die and a second die to the redistribution portion. In some implementations, a set of interconnects (e.g., pillar, solder) are used to couple the first and second dies to the redistribution portion.

The method also provides (at 1445) a fill between the first and second dies and the redistribution portion The fill may include a non-conducting fill (NCF) and/or a non-conducting paste (NCP).

The method removes (at 1450) the second carrier leaving the package portion. Different implementations may remove the second carrier differently.

### Exemplary Semi-Additive Patterning (SAP) Process

Various interconnects (e.g., traces, vias, pads) are described in the present disclosure. These interconnects may be formed in the photo imageable layer, the base portion, the silicon bridge, and/or the redistribution portion. In some implementations, these interconnects may includes one or more metal layers. For example, in some implementations, these interconnects may include a first metal seed layer and a second metal layer. The metal layers may be provided (e.g., formed) using different plating processes. Below are detailed examples of interconnects (e.g., traces, vias, pads) with seed layers and how these interconnects may be formed using different plating processes.

Different implementations may use different processes to form and/or fabricate the metal layers (e.g., interconnects, redistribution layer, under bump metallization layer,). In some implementations, these processes include a semi-additive patterning (SAP) process and a damascene process. These various different processes are further described below.

FIG. 15 illustrates a sequence for forming an interconnect using a semi-additive patterning (SAP) process to provide and/or form an interconnect in one or more dielectric layer(s). As shown in FIG. 15, stage 1 illustrates a state of an integrated device (e.g., substrate) after a dielectric layer 1502 is provided (e.g., formed). In some implementations, stage 1 illustrates that the dielectric layer 1502 includes a first metal layer 1504. The first metal layer 1504 is a seed layer in some implementations. In some implementations, the first metal layer 1504 may be provided (e.g., formed) on the dielectric layer 1502 after the dielectric layer 1502 is provided (e.g., received or formed). Stage 1 illustrates that the first metal layer 1504 is provided (e.g., formed) on a first surface of the dielectric layer 1502. In some implementations, the first metal layer 1504 is provided by using a deposition process (e.g., PVD, CVD, plating process).

Stage 2 illustrates a state of the integrated device after a photo resist layer 1506 (e.g., photo develop resist layer) is selectively provided (e.g., formed) on the first metal layer 1504. In some implementations, selectively providing the resist layer 1506 includes providing a first resist layer 1506 on the first metal layer 1504 and selectively removing portions of the resist layer 1506 by developing (e.g., using a development process). Stage 2 illustrates that the resist layer 1506 is provided such that a cavity 1508 is formed.

Stage 3 illustrates a state of the integrated device after a second metal layer 1510 is formed in the cavity 1508. In some implementations, the second metal layer 1510 is formed over an exposed portion of the first metal layer 1504. In some implementations, the second metal layer 1510 is provided by using a deposition process (e.g., plating process).

Stage 4 illustrates a state of the integrated device after the resist layer 1506 is removed. Different implementations may use different processes for removing the resist layer 1506.

Stage 5 illustrates a state of the integrated device after portions of the first metal layer 1504 are selectively removed. In some implementations, one or more portions of the first metal layer 1504 that is not covered by the second metal layer 1510 is removed. As shown in stage 5, the remaining first metal layer 1504 and the second metal layer 1510 may form and/or define an interconnect 1512 (e.g., trace, vias, pads) in an integrated device and/or a substrate. In some implementations, the first metal layer 1504 is removed such that a dimension (e.g., length, width) of the first metal layer 1504 underneath the second metal layer 1510 is about the same or smaller than a dimension (e.g., length, width) of the second metal layer 1510, which can result in an undercut, as shown at stage 5 of FIG. 15. In some implementations, the above mentioned processes may be iterated several times to provide and/or form several interconnects in one or more dielectric layers of an integrated device and/or substrate.

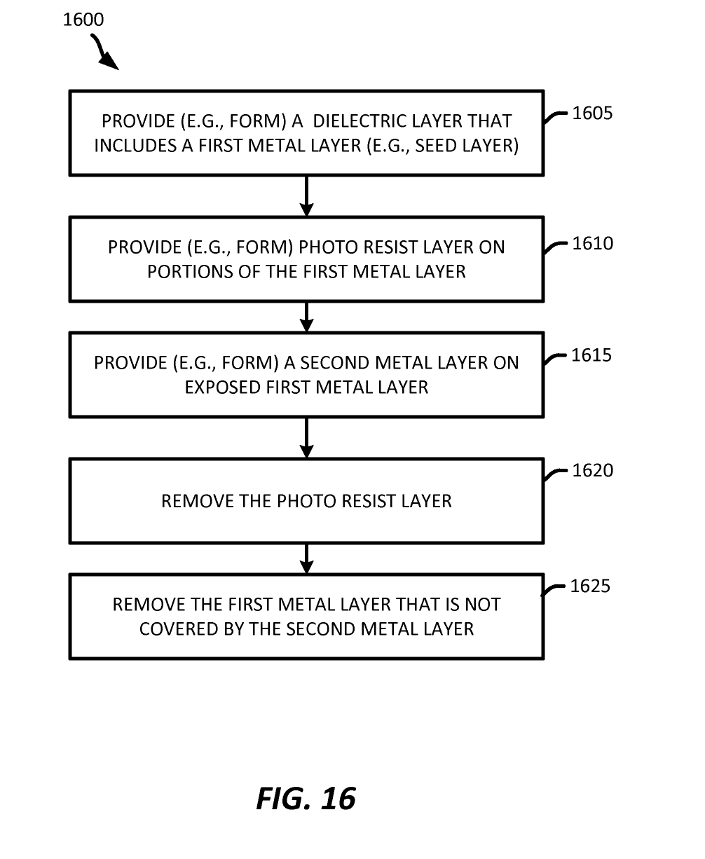

FIG. 16 illustrates a flow diagram for a method for using a (SAP) process to provide and/or form an interconnect in one or more dielectric layer(s). The method provides (at 1605) a dielectric layer (e.g., dielectric layer 1502). In some implementations, providing the dielectric layer includes forming the dielectric layer. In some implementations, providing the dielectric layer includes forming a first metal layer (e.g., first metal layer 1504). The first metal layer is a seed layer in some implementations. In some implementations, the first metal layer may be provided (e.g., formed) on the dielectric layer after the dielectric layer is provided (e.g., received or formed). In some implementations, the first metal layer is provided by using a deposition process (e.g., physical vapor deposition (PVD) or plating process).

The method selectively provides (at 1610) a photo resist layer (e.g., a photo develop resist layer 1506) on the first metal layer. In some implementations, selectively providing the resist layer includes providing a first resist layer on the first metal layer and selectively removing portions of the resist layer (which provides one or more cavities).

The method then provides (at 1615) a second metal layer (e.g., second metal layer 1510) in the cavity of the photo resist layer. In some implementations, the second metal layer is formed over an exposed portion of the first metal layer. In some implementations, the second metal layer is provided by using a deposition process (e.g., plating process).

The method further removes (at 1620) the resist layer. Different implementations may use different processes for removing the resist layer. The method also selectively removes (at 1625) portions of the first metal layer. In some implementations, one or more portions of the first metal layer that is not covered by the second metal layer are removed. In some implementations, any remaining first metal layer and second metal layer may form and/or define one or more interconnects (e.g., trace, vias, pads) in an integrated device and/or a substrate. In some implementations, the above mentioned method may be iterated several times to provide and/or form several interconnects in one or more dielectric layers of an integrated device and/or substrate.

### Exemplary Damascene Process

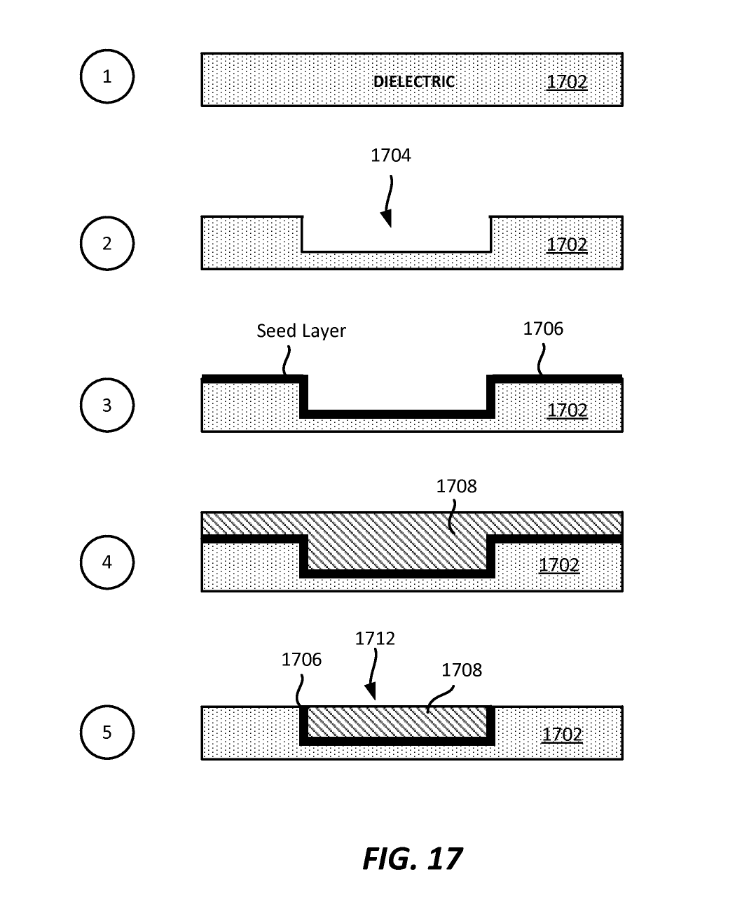

FIG. 17 illustrates a sequence for forming an interconnect using a damascene process to provide and/or form an interconnect in a dielectric layer. As shown in FIG. 17, stage 1 illustrates a state of an integrated device after a dielectric layer 1702 is provided (e.g., formed). In some implementations, the dielectric layer 1702 is an inorganic layer (e.g., inorganic film).

Stage 2 illustrates a state of an integrated device after a cavity 1704 is formed in the dielectric layer 1702. Different implementations may use different processes for providing the cavity 1704 in the dielectric layer 1702.

Stage 3 illustrates a state of an integrated device after a first metal layer 1706 is provided on the dielectric layer 1702. As shown in stage 3, the first metal layer 1706 provided on a first surface of the dielectric layer 1702. The first metal layer 1706 is provided on the dielectric layer 1702 such that the first metal layer 1706 takes the contour of the dielectric layer 1702 including the contour of the cavity 1704. The first metal layer 1706 is a seed layer in some implementations. In some implementations, the first metal layer 1706 is provided by using a deposition process (e.g., physical vapor deposition (PVD), Chemical Vapor Deposition (CVD) or plating process).

Stage 4 illustrates a state of the integrated device after a second metal layer 1708 is formed in the cavity 1704 and a surface of the dielectric layer 1702. In some implementations, the second metal layer 1708 is formed over an exposed portion of the first metal layer 1706. In some implementations, the second metal layer 1708 is provided by using a deposition process (e.g., plating process).

Stage 5 illustrates a state of the integrated device after the portions of the second metal layer 1708 and portions of the first metal layer 1706 are removed. Different implementations may use different processes for removing the second metal layer 1708 and the first metal layer 1706. In some implementations, a chemical mechanical planarization (CMP) process is used to remove portions of the second metal layer 1708 and portions of the first metal layer 1706. As shown in stage 5, the remaining first metal layer 1706 and the second metal layer 1708 may form and/or define an interconnect 1712 (e.g., trace, vias, pads) in an integrated device and/or a substrate. As shown in stage 5, the interconnect 1712 is formed in such a way that the first metal layer 1706 is formed on the base portion and the side portion(s) of the second metal layer 1710. In some implementations, the cavity 1704 may include a combination of trenches and/or holes in two levels of dielectrics so that via and interconnects (e.g., metal traces) may be formed in a single deposition step, In some implementations, the above mentioned processes may be iterated several times to provide and/or form several interconnects in one or more dielectric layers of an integrated device and/or substrate.

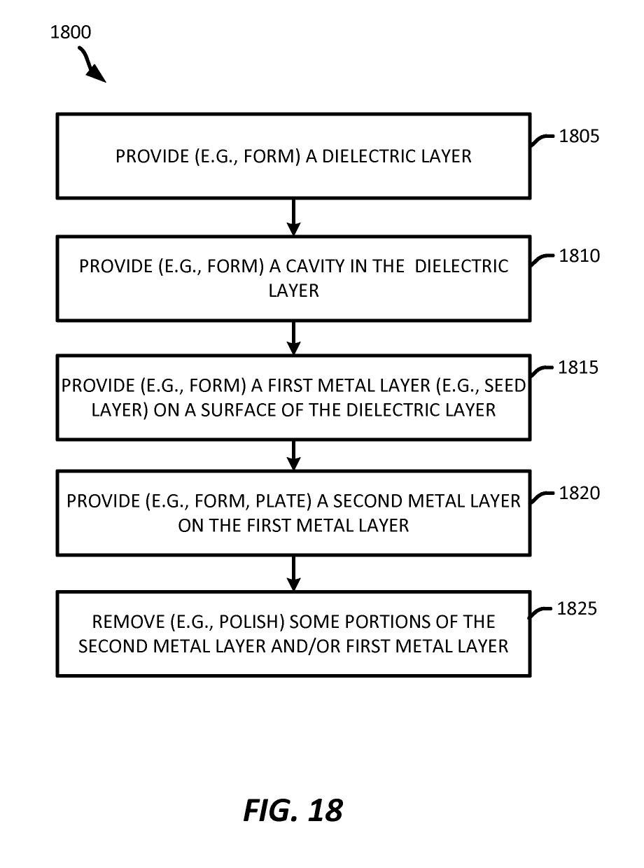

FIG. 18 illustrates a flow diagram of a method 1800 for forming an interconnect using a damascene process to provide and/or form an interconnect in a dielectric layer. The method provides (at 1805) a dielectric layer (e.g., dielectric layer 1702). In some implementations, providing a dielectric layer includes forming a dielectric layer. In some implementations, providing a dielectric layer includes receiving a dielectric layer from a supplier. In some implementations, the dielectric layer is an inorganic layer (e.g., inorganic film).

The method forms (at 1810) at least one cavity (e.g., cavity 1704) in the dielectric layer. Different implementations may use different processes for providing the cavity in the dielectric layer.

The method provides (at 1815) a first metal layer (e.g., first metal layer 1706) on the dielectric layer. In some implementations, the first metal layer is provided (e.g., formed) on a first surface of the dielectric later. In some implementations, the first metal layer is provided on the dielectric layer such that the first metal layer takes the contour of the dielectric layer including the contour of the cavity. The first metal layer is a seed layer in some implementations. In some implementations, the first metal layer 1706 is provided by using a deposition process (e.g., PVD, CVD or plating process).

The method provides (at 1820) a second metal layer (e.g., second metal layer 1708) in the cavity and a surface of the dielectric layer. In some implementations, the second metal layer is formed over an exposed portion of the first metal layer. In some implementations, the second metal layer is provided by using a deposition process (e.g., plating process). In some implementations, the second metal layer is similar or identical to the first metal layer. In some implementations, the second metal layer is different than the first metal layer.

The method then removes (at 1825) portions of the second metal layer and portions of the first metal layer. Different implementations may use different processes for removing the second metal layer and the first metal layer. In some implementations, a chemical mechanical planarization (CMP) process is used to remove portions of the second metal layer and portions of the first metal layer. In some implementations, the remaining first metal layer and the second metal layer may form and/or define an interconnect (e.g., interconnect 1712). In some implementations, an interconnect may include one of at least a trace, a via, and/or a pad) in an integrated device and/or a substrate. In some implementations, the interconnect is formed in such a way that the first metal layer is formed on the base portion and the side portion(s) of the second metal layer. In some implementations, the above mentioned method may be iterated several times to provide and/or form several interconnects in one or more dielectric layers of an integrated device and/or substrate.

### Exemplary Package-on-Package (PoP) Structure Comprising Silicon Bridge in Photo Imageable Layer

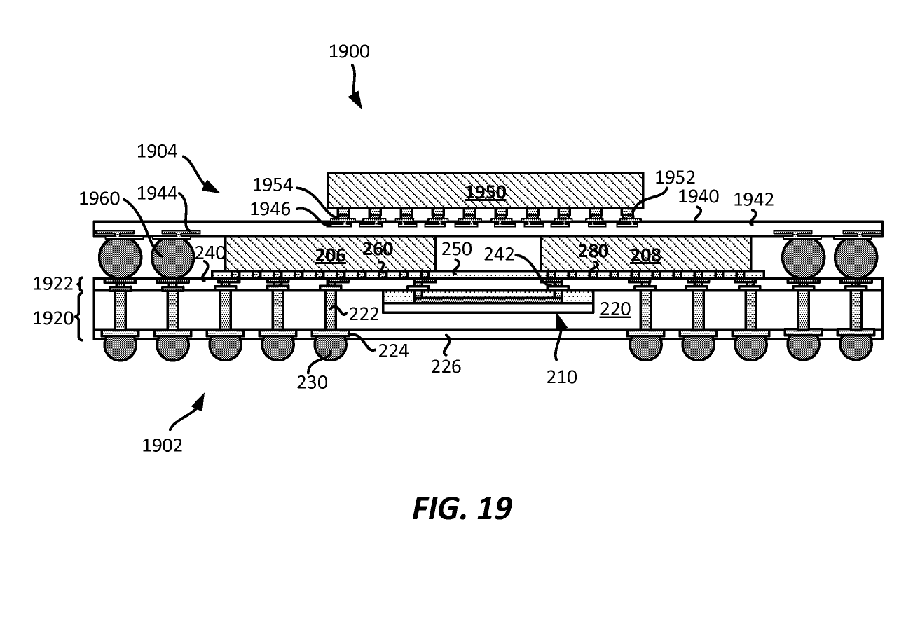

In some implementations, an integrated device package that includes high density die-to-die interconnects may be implemented in a package-on-package (PoP) structure. FIG. 19 illustrates an example of a PoP structure 1900 that includes high density die-to-die interconnects. As shown in FIG. 19, the PoP structure 1900 includes a first integrated device package 1902 and a second integrated device package 1904. The second integrated device package 1904 is coupled to the first integrated device package 1902. As shown in FIG. 19, the second integrated device package 1904 is positioned above the first integrated device package 1902.

The first integrated device package 1902 includes a base portion 1920, a redistribution portion 1922, the first die 206, the second die 208, and the silicon bridge 210. The silicon bridge 210 is configured to provide high density die-to-die interconnects in the first integrated device package 1902. The first die 206 is coupled to the redistribution portion 1922 through the set of interconnects 260. Similarly, the second die 208 is coupled to the redistribution portion 1922 through the set of interconnects 280. The base portion 1920 and the redistribution portion 1922 may define an integrated device package base (e.g., package substrate) of the first integrated device package 1902. The first integrated device package 1902 may be similar or configured in a similar manner as the integrated device package 200 of FIG. 2 or any of the integrated device packages described in the present disclosure.

The base portion 1920 includes the photo imageable layer 220, the set of vias 222, the set of pads 224, and the solder resist layer 226. In some implementations, the photo imageable layer 220 is a material that is photo etchable. That is, the photo imageable layer 220 is made of a material that can be etched and/or removed through the exposure of the material to a light source (e.g., ultraviolet (UV) light). The set of vias 222 vertically traverses the photo imageable layer 220. The set of pads 224 is coupled to the set of vias 222. The solder resist layer 226 covers a first surface (e.g., bottom surface) of the photo imageable layer 220. A first set of solder balls 230 is coupled to the first set of pads 224. Examples of base portions are described in detail in at least FIGS. 5-10.

FIG. 19 illustrates that the silicon bridge 210 is at least partially embedded in the photo imageable layer 220 of the base portion 1920. The silicon bridge 210 is configured to provide high density interconnects in the base portion 1920. The silicon bridge 210 may include a substrate, a set of interconnects (e.g., set of high density interconnects), a set of vias, and a dielectric layer. In some implementations, the set of interconnects in the silicon bridge 210 has a higher density than the density of the set of vias 222 in the photo imageable layer 220. An example of a bridge (e.g., silicon bridge) is described in detail in at least FIGS. 3-4.

The redistribution portion 1922 includes the set of dielectric layers 240, and the set of interconnects 242. As shown in FIG. 19, the redistribution portion 204 is coupled to a second surface (e.g., top surface) of the base portion 1920. The redistribution portion 1922 is formed over a second surface (e.g., top surface) of the photo imageable layer 220 and the silicon bridge 210. The set of dielectric layers 240 may include one or more dielectric layers. The set of interconnects 242 may include traces, vias, pillars, posts, and/or pads. The set of interconnects 242 is coupled to the set of vias 222 and the silicon bridge 210. Examples of various redistribution portions are described in detail in at least FIGS. 5-10.

The second integrated device package 1904 includes a package substrate 1940, a third die 1950 and a set of solder balls 1960. The package substrate 1940 includes a dielectric layer 1942, a first set of interconnects 1944, and a second set of interconnects 1946. The first set of interconnects 1944 and the second set of interconnects 1946 may include traces, vias, pads, and/or pillars. The first set of interconnects 1944 is coupled to the second set of interconnects 1946 and the set of solder balls 1960. The set of solder balls 1960 may be coupled to the set of interconnects 242 in the redistribution portion 1922 of the first integrated device package 1902.

The third die 1950 is coupled to the second set of interconnects 1946 through a set of pillars 1952 and a set of solder 1954. In some implementations, the third die 1950 in the second integrated device package 1904 may be electrically coupled to the first integrated device package 1902 through an electrical path that includes the set of pillars 1952, the set of solder 1954, the second set of interconnects 1946, the first set of interconnects 1944, the set of solder balls 1960 and/or the set of interconnects 242. In some implementations, an encapsulation layer (not shown) may encapsulate the third die 1950.

### Exemplary Electronic Devices

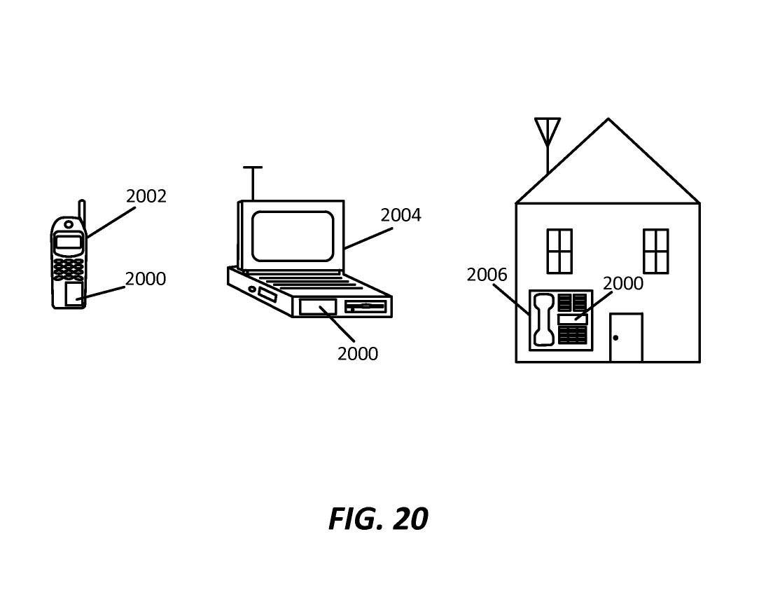

FIG. 20 illustrates various electronic devices that may be integrated with any of the aforementioned integrated device, semiconductor device, integrated circuit, die, interposer, package or package-on-package (PoP). For example, a mobile telephone 2002, a laptop computer 2004, and a fixed location terminal 2006 may include an integrated device 2000 as described herein. The integrated device 2000 may be, for example, any of the integrated circuits, dice, packages, package-on-packages described herein. The devices 2002, 2004, 2006 illustrated in FIG. 20 are merely exemplary. Other electronic devices may also feature the integrated device 2000 including, but not limited to, mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, or any other device that stores or retrieves data or computer instructions, or any combination thereof

One or more of the components, steps, features, and/or functions illustrated in FIGS. 2, 3, 4, 5, 6, 7, 8, 9, 10, 11, 12, 13A-13D, 14, 15, 16, 17, 18, 19 and/or 20 may be rearranged and/or combined into a single component, step, feature or function or embodied in several components, steps, or functions. Additional elements, components, steps, and/or functions may also be added without departing from the disclosure. It should also be noted that FIGS. 2, 3, 4, 5, 6, 7, 8, 9, 10, 11, 12, 13A-13D, 14, 15, 16, 17, 18, 19 and/or 20 and its corresponding description in the present disclosure is not limited to dies and/or ICs. In some implementations, FIGS. 2, 3, 4, 5, 6, 7, 8, 9, 10, 11, 12, 13A-13D, 14, 15, 16, 17, 18, 19 and/or 20 and its corresponding description may be used to manufacture, create, provide, and/or produce integrated devices. In some implementations, a device may include a die, a die package, an integrated circuit (IC), an integrated device, an integrated device package, a wafer, a semiconductor device, a package on package structure, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other.

Also, it is noted that the embodiments may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. An integrated device package base comprising:
a base portion comprising:
a photo imageable layer;
a bridge, at least partially embedded in the photo imageable layer, configured to provide an electrical path between a first die and a second die, the bridge comprising a first set of interconnects comprising a first density of interconnection; and
a set of vias, in the photo imageable layer, comprising a second density of interconnection; and
a redistribution portion coupled to the base portion and the redistribution portion comprising:
at least one dielectric layer;
a second set of interconnects coupled to the first set of interconnects; and
a third set of interconnects coupled to the set of vias.

2. The integrated device package base of claim 1, wherein the first density of interconnection of the first set of interconnects is less than the second density of interconnection of the set of vias.

3. The integrated device package base of claim 1, wherein the first density of interconnection of the first set of interconnects comprises a width of about 2 microns (μm) or less, and/or a spacing of about 2 microns (μm) or less.

4. The integrated device package base of claim 1, wherein the electrical path between the first die and the second die comprises the first set of interconnects in the bridge and the second set of interconnects in the redistribution portion.

5. The integrated device package base of claim 1, wherein the first set of interconnects comprises one of at least a trace, a via, and/or a pad.

6. The integrated device package base of claim 1, wherein the second set of interconnects comprises one of at least a redistribution interconnect, a trace, a via, and/or a pad.

7. The integrated device package base of claim 1, wherein the integrated device package base is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

8. An integrated device package base comprising:
a base portion comprising:
a photo imageable layer;
a bridge means, at least partially embedded in the photo imageable layer, configured to provide an electrical path between a first die and a second die; and
a set of vias in the photo imageable layer; and
a redistribution portion coupled to the base portion, the redistribution portion comprising:
at least one dielectric layer;
a first set of interconnects coupled to the bridge means; and
a second set of interconnects coupled to the set of vias.

9. The integrated device package base of claim 8, wherein the bridge means includes a third set of interconnects comprising a first density of interconnection, the first density of interconnection comprising a width of about 2 microns (μm) or less, and/or a spacing of about 2 microns (μm) or less.

10. The integrated device package base of claim 9, wherein the third set of interconnects comprises one of at least a trace, a via, and/or a pad.

11. The integrated device package base of claim 9, wherein the electrical path between the first die and the second die comprises the third set of interconnects in the bridge and the first set of interconnects in the redistribution portion.

12. The integrated device package base of claim 8, wherein the second set of interconnects comprises one of at least a redistribution interconnect, a trace, a via, and/or a pad.

13. The integrated device package base of claim 8, wherein the integrated device package base is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

14. An integrated device package comprising:
a base portion comprising:
a photo imageable layer;
a bridge, at least partially embedded in the photo imageable layer, comprising a first set of interconnects comprising a first density of interconnection; and
a set of vias, in the photo imageable layer, comprising a second density of interconnection;
a redistribution portion coupled to the base portion, the redistribution portion comprising:
at least one dielectric layer;
a second set of interconnects coupled to the first set of interconnects; and
a third set of interconnects coupled to the set of vias;
a first die coupled to the redistribution portion; and
a second die coupled to the redistribution portion, wherein the first die and the second die are coupled to each other through an electrical path that includes the bridge.

15. The integrated device package of claim 14, wherein the first density of interconnection of the first set of interconnects is less than the second density of interconnection of the set of vias.

16. The integrated device package of claim 14, wherein the first density of interconnection of the first set of interconnects comprises a width of about 2 microns (μm) or less, and/or a spacing of about 2 microns (μm) or less.

17. The integrated device package of claim 14, wherein the electrical path between the first die and the second die comprises the first set of interconnects in the bridge and the second set of interconnects in the redistribution portion.

18. The integrated device package of claim 14, wherein the first set of interconnects comprises one of at least a trace, a via, and/or a pad.

19. The integrated device package of claim 14, wherein the second set of interconnects comprises one of at least a redistribution interconnect, a trace, a via, and/or a pad.

20. The integrated device package of claim 14, further comprising a fill between the first die and the redistribution portion.

21. The integrated device package of claim 14, wherein the integrated device package is a first integrated device package of a package-on-package (PoP) structure.

22. The integrated device package of claim 14, wherein the integrated device package is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.

23. An integrated device package comprising:
a base portion comprising:
a photo imageable layer;
a bridge means at least partially embedded in the photo imageable layer,
a set of vias in the photo imageable layer; and
a redistribution portion, coupled to the base portion, comprising:
at least one dielectric layer;
a first set of interconnects coupled to the bridge means; and
a second set of interconnects coupled to the set of vias;
a first die coupled to the redistribution portion; and
a second die coupled to the redistribution portion, wherein the first die and the second die are coupled to each other through an electrical path that includes the bridge means, wherein the bridge means is configured to provide the electrical path between the first die and the second die.

24. The integrated device package of claim 23, wherein the bridge means includes a third set of interconnects comprising a first density of interconnection, the first density of interconnection comprising a width of about 2 microns (μm) or less, and/or a spacing of about 2 microns (μm) or less.

25. The integrated device package of claim 24, wherein the third set of interconnects comprises one of at least a trace, a via, and/or a pad.

26. The integrated device package of claim 24, wherein the electrical path between the first die and the second die comprises the third set of interconnects in the bridge means and the first set of interconnects in the redistribution portion.

27. The integrated device package of claim 23, wherein the second set of interconnects comprises one of at least a redistribution interconnect, a trace, a via, and/or a pad.

28. The integrated device package of claim 23, further comprising a fill between the first die and the redistribution portion.

29. The integrated device package of claim 23, wherein the integrated device package is a first integrated device package of a package-on-package (PoP) structure.

30. The integrated device package of claim 23, wherein the integrated device package is incorporated into at least one of a music player, a video player, an entertainment unit, a navigation device, a communications device, a mobile device, a mobile phone, a smartphone, a personal digital assistant, a fixed location terminal, a tablet computer, a computer, a wearable device, and/or a laptop computer.
